(19) United States
(12) Patent Application Publication
(10) Pub. No.: US 2024/0365622 A1
(43) Pub. Date: Oct. 31, 2024

(54) DISPLAY DEVICE

(71) Applicant: Samsung Display Co., Ltd., Yongin-si (KR)

(72) Inventors: Il Ha SONG, Yongin-si (KR); Hyo Min KO, Yongin-si (KR); Sang Gyun KIM, Yongin-si (KR); Dae Woong LEE, Yongin-si (KR); Hyeon Jeong IM, Yongin-si (KR); Hye Won CHOI, Yongin-si (KR)

(21) Appl. No.: 18/528,592

(22) Filed: Dec. 4, 2023

(30) Foreign Application Priority Data
Apr. 28, 2023 (KR) 10-2023-0055911

(51) Int. Cl. H10K 59/179; H10K 59/122; H10K 59/32; H10K 59/38

(52) U.S. Cl. CPC H10K 59/179; H10K 59/122; H10K 59/32; H10K 59/38

(57) ABSTRACT

A display device includes: a first pixel electrode comprising a first reflective electrode in a first emission area, a first light transmitting pattern on the first reflective electrode, and a first light transmitting electrode on the first reflective electrode and the first light transmitting pattern and connected to the first reflective electrode; a second pixel electrode comprising a second reflective electrode in a second emission area and a second light transmitting electrode on the second reflective electrode; a light emitting stack on the first and second pixel electrodes and comprising at least one light emitting layer; a common electrode on the light emitting stack; and a bank pattern surrounding the first and second emission areas, and having at least a portion between the first emission area and the second emission area, wherein the first light transmitting pattern and the bank pattern contain a same material and are spaced apart.

### CROSS-REFERENCE TO RELATED APPLICATION

The present application claims priority to and the benefit of Korean Patent Application No. 10-2023-0055911, filed on Apr. 28, 2023, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

The importance of display devices has steadily increased with the development of multimedia technology. Accordingly, various types of display devices such as liquid crystal display devices, organic light emitting display devices and the like have been developed.

Recently, virtual reality (VR) and augmented reality (AR) display devices based on a head mounted display (HMD) has been spotlighted as a next-generation display device. In the case of VR and AR display devices used at a short distance, a screen door effect (SDE) must be minimized, a sense of distance may desirably be maintained, and high-speed driving may be desirable to minimize or reduce afterimages in fast motion. Accordingly, a display device with relatively high resolution and relatively high luminance is required.

The above information disclosed in this Background section is only for enhancement of understanding of the background and therefore the information discussed in this Background section does not necessarily constitute prior art.

### SUMMARY

Aspects of some embodiments of the present disclosure include a display device with relatively high resolution and relatively high luminance.

However, aspects of some embodiments of the present disclosure are not restricted to those set forth herein. The above and other aspects of some embodiments of the present disclosure will become more apparent to one of ordinary skill in the art to which the present disclosure pertains by referencing the detailed description of the present disclosure given below.

According to some embodiments of the present disclosure, a display device includes a first pixel electrode including a first reflective electrode in a first emission area, a first light transmitting pattern on a part of the first reflective electrode and containing an insulating material, and a first light transmitting electrode on the first reflective electrode and the first light transmitting pattern and connected to the first reflective electrode, a second pixel electrode including a second reflective electrode in a second emission area and a second light transmitting electrode on the second reflective electrode, a light emitting stack on the first pixel electrode and the second pixel electrode and including at least one light emitting layer, and a common electrode on the light emitting stack, wherein the first light transmitting pattern is a separation type pattern locally on the first reflective electrode, the light emitting stack is a common layer entirely over a display area including the first emission area and the second emission area, and a first distance between the first reflective electrode and the common electrode is greater than a second distance between the second reflective electrode and the common electrode.

According to some embodiments, the display device may further include a bank pattern between the first pixel electrode and the second pixel electrode, containing the same insulating material as the first light transmitting pattern, and spaced apart from the first light transmitting pattern.

According to some embodiments, the bank pattern may surround the first emission area and the second emission area, and at least a part of the bank pattern may be located between the first emission area and the second emission area.

According to some embodiments, the display device may further include a first color filter on the common electrode to correspond to the first emission area, and selectively transmitting light of a first color, and a second color filter on the common electrode to correspond to the second emission area, and selectively transmitting light of a second color.

According to some embodiments, the first distance may correspond to a resonance distance of the light of the first color, and the second distance may correspond to a resonance distance of the light of the second color.

According to some embodiments, the common electrode may be a semi-transmissive type thin film electrode containing metal.

According to some embodiments, the display device may further include a third pixel electrode including a third reflective electrode in a third emission area, a second light transmitting pattern on a part of the third reflective electrode, and a third light transmitting electrode on the third reflective electrode and the second light transmitting pattern and connected to the third reflective electrode, and a part of each of the light emitting stack and the common electrode may be on the third pixel electrode.

According to some embodiments, the first light transmitting pattern and the second light transmitting pattern may contain the same insulating material and have different thicknesses.

According to some embodiments, the second pixel electrode may further include a third light transmitting pattern on a part of the second reflective electrode and containing an insulating material, and the second light transmitting electrode may be on the second reflective electrode and the third light transmitting pattern and may be connected to the second reflective electrode.

According to some embodiments, the first light transmitting pattern, the second light transmitting pattern, and the third light transmitting pattern may contain the same insulating material.

According to some embodiments, the light emitting stack may include a first light emitting layer emitting light of a first color, and a second light emitting layer emitting light of a second color.

According to some embodiments, the light emitting stack may include a first stack including the first light emitting layer, and a first hole layer and a first electron layer overlapping each other with the first light emitting layer interposed therebetween, and a second stack on the first stack, and including the second light emitting layer, and a second hole layer and a second electron layer overlapping each other with the second light emitting layer interposed therebetween.

According to some embodiments, the light emitting stack may further include a third stack overlapping the first stack and the second stack and including a third light emitting layer emitting the light of the first color, and a third hole layer and a third electron layer overlapping each other with the third light emitting layer interposed therebetween.

According to some embodiments, the first stack may be closer to the first pixel electrode and the second pixel electrode than the second stack and the third stack, and the first light emitting layer may emit blue light.

According to some embodiments of the present disclosure, a display device includes a first pixel electrode including a first reflective electrode in a first emission area, a first light transmitting pattern on a part of the first reflective electrode, and a first light transmitting electrode on the first reflective electrode and the first light transmitting pattern and connected to the first reflective electrode, a second pixel electrode including a second reflective electrode in a second emission area and a second light transmitting electrode on the second reflective electrode, a light emitting stack on the first pixel electrode and the second pixel electrode and including at least one light emitting layer, a common electrode on the light emitting stack, and a bank pattern surrounding the first emission area and the second emission area, and having at least a portion positioned between the first emission area and the second emission area, wherein the first light transmitting pattern and the bank pattern contain the same material and are spaced apart from each other.

According to some embodiments, the first light transmitting pattern may be a separation type pattern locally on the first reflective electrode, and the light emitting stack may be a common layer entirely over a display area including the first emission area and the second emission area.

According to some embodiments, the light emitting stack may include a first light emitting layer emitting light of a first color, and a second light emitting layer emitting light of a second color.

According to some embodiments, the display device may further include a first color filter on the common electrode to correspond to the first emission area, and selectively transmitting light of a first color, and a second color filter on the common electrode to correspond to the second emission area, and selectively transmitting light of a second color.

According to some embodiments, a first distance between the first reflective electrode and the common electrode may correspond to a resonance distance of the light of the first color, and a second distance between the second reflective electrode and the common electrode may correspond to a resonance distance of the light of the second color.

According to some embodiments, the light emitting stack may include a first stack including the first light emitting layer and at least one first intermediate layer, a second stack on the first stack, and including the second light emitting layer and at least one second intermediate layer, and a third stack on the second stack, and including a third light emitting layer and at least one third intermediate layer. The first light emitting layer may emit blue light.

The display device according to some embodiments includes light emitting elements including light emitting stacks located and/or formed entirely over a display area including emission areas of pixels. In addition, the display device according to some embodiments may include light transmitting patterns provided in at least some emission areas, and a distance between a reflective electrode and a common electrode may be different according to light emitted from each pixel. According to some embodiments, the distance between the reflective electrode and the common electrode of each pixel may vary according to whether a light transmitting pattern is included and/or the thickness of the light transmitting pattern, and may correspond to a resonance distance of light emitted from the corresponding pixel. According to some embodiments, the display device having relatively high resolution, relatively high luminance, and relatively high efficiency may be provided.

However, characteristics according to some embodiments of the present disclosure are not limited to those described above and various other characteristics are incorporated herein.

### BRIEF DESCRIPTION OF THE DRAWINGS

The above and other aspects and characteristics of embodiments according to the present disclosure will become more apparent by describing in more detail aspects of some embodiments thereof with reference to the attached drawings, in which:

FIG. 1 is a plan view illustrating a display device DD according to some embodiments;

FIG. 2 is a plan view illustrating the display device DD according to some embodiments;

FIG. 3 is a cross-sectional view schematically illustrating a structure of the display device according to some embodiments;

FIG. 4 is a cross-sectional view schematically illustrating a structure of the display device according to some embodiments;

FIGS. 5 to 8 are plan views illustrating the display area of the display device according to some embodiments;

FIG. 9 is a plan view illustrating the display device according to some embodiments;

FIG. 10 is a cross-sectional view schematically illustrating a traveling path of light generated by a light emitting stack according to some embodiments;

FIG. 11 is a cross-sectional view schematically illustrating a resonance waveform of light generated between a reflective electrode and a common electrode according to some embodiments;

FIG. 12 is a graph illustrating the micro-cavity effect of light generated from a light emitting element according to some embodiments;

FIGS. 13 to 16 are cross-sectional views illustrating the display device according to some embodiments;

FIGS. 17 to 23 are cross-sectional views schematically showing the structure of the light emitting element according to some embodiments;

FIG. 24 is a graph illustrating spectrums of light emitted from the first light emitting layer, the second light emitting layer, and the third light emitting layer of the light emitting element according to some embodiments; and

FIG. 25 is a graph illustrating spectrums of light emitted from the light emitting elements according to some embodiments.

### DETAILED DESCRIPTION

Aspects of some embodiments of the present invention will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will more fully convey the scope of embodiments according to the present invention to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

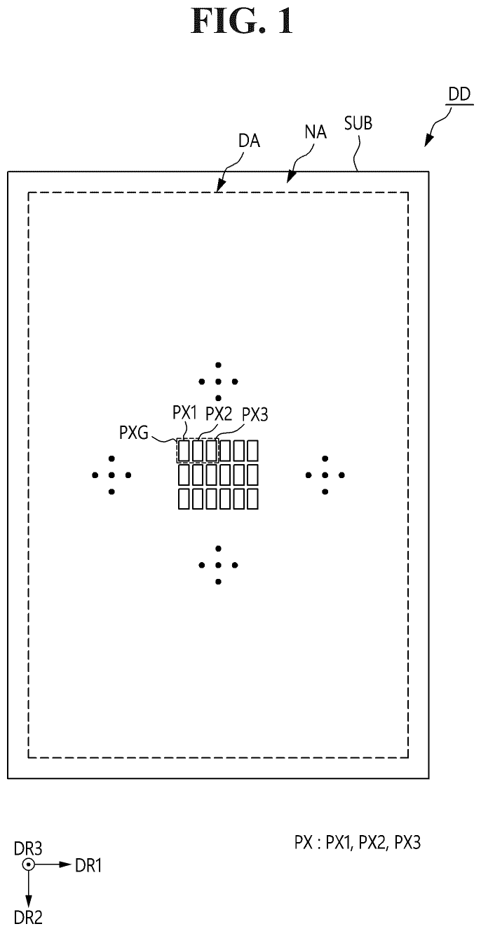

FIG. 1 is a plan view illustrating a display device DD according to some embodiments. For example, FIG. 1 schematically shows the display device DD having a quadrangular shape.

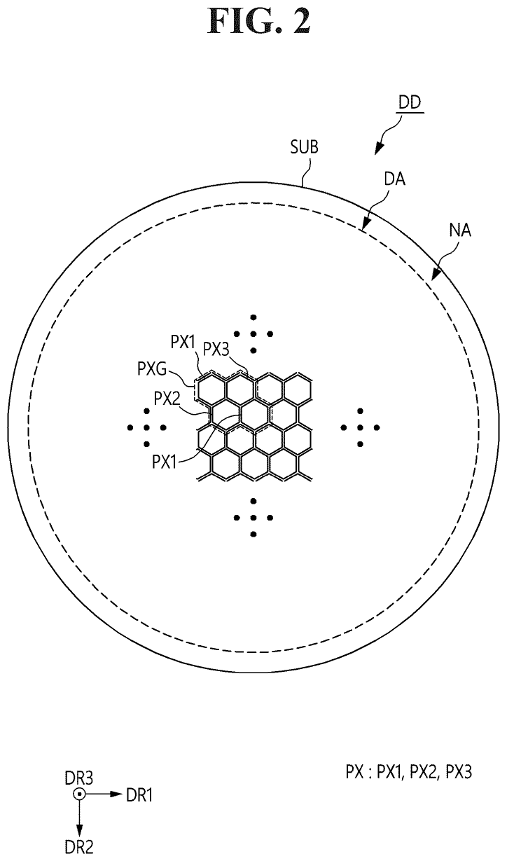

FIG. 2 is a plan view illustrating the display device DD according to some embodiments. For example, FIG. 2 is a view illustrating aspects of the shape of the pixels PX and the display device DD, the arrangement structure of the pixels PX, or the like according to some embodiments, and schematically illustrates the display device DD having a circular shape. Embodiments according to the present disclosure, however, are not limited thereto.

In FIGS. 1 and 2, the structure of the display device DD is briefly illustrated centering on a display panel including a display area DA. The display device DD may further include a driving circuit (e.g., a scan driver, a data driver, and a timing controller) to drive the pixels PX. According to some embodiments, at least a part of the driving circuit may be formed and/or located inside the display panel, and according to some embodiments, the driving circuit may be provided outside the display panel and electrically connected to the display panel.

Referring to FIGS. 1 and 2, the display device DD may include a substrate SUB and pixels PX located on the substrate SUB.

The substrate SUB may be a base member for manufacturing or providing the display device DD, and may constitute, for example, a base surface of the display device DD. The substrate SUB may include the display area DA in which the pixels PX are located, and a non-display area NA excluding the display area DA. The display area DA may be an area in which an image is displayed, and the non-display area NA may be an area other than the display area DA.

The display device DD may be provided in various shapes. According to some embodiments, the display device DD may be provided as a quadrilateral panel as illustrated in FIG. 1. In FIG. 1, the display device DD is illustrated as including an angular corner, but the display device DD may include a rounded corner. According to some embodiments, the display device DD may be provided as a circular panel or may be provided as an elliptical panel as illustrated in FIG. 2. In addition, the display device DD may have various shapes.

According to some embodiments, the display device DD may be provided as a substantially flat 2D panel or may be provided as a 3D panel having curves in a thickness direction or the like. The display device DD may be a rigid display device that is not substantially transformed or may be a flexible display device that may be transformed in at least a part thereof, such as being folded, bent, or rolled.

For convenience, in FIGS. 1 and 2, the display device DD is illustrated as having a rectangular or circular flat plate shape. In addition, the horizontal direction (row direction or X direction) of the display device DD is referred to as a first direction DR1, the vertical direction (column direction or Y direction) of the display device DD is referred to as a second direction DR2, and the thickness direction (or height direction) of the display device DD is referred to as a third direction DR3.

The display area DA may have various shapes. For example, the display area DA may have a rectangular shape as in the embodiments of FIG. 1 or may have a circular shape as in the embodiments of FIG. 2. In addition, the display area DA may have various shapes.

According to some embodiments, the display area DA may have a shape conforming to the shape of the display device DD. For example, when the display device DD is provided in a quadrilateral shape, the display area DA may be provided in a quadrilateral shape that conforms to the size and/or shape of the display device DD. Alternatively, when the display device DD is provided in a circular shape or an elliptical shape, the display area DA may be provided in a circular shape or an elliptical shape that conforms to the size and/or shape of the display device DD.

However, embodiments according to the present disclosure are not limited thereto. For example, the display area DA may have a shape different from that of the display device DD.

The pixels PX may be arranged in the display area DA. For example, the display area DA may include a plurality of pixel areas in which the respective pixels PX are provided and/or located, and the pixels PX may be located in pixel areas on the substrate SUB, respectively.

The display device DD may include the pixels PX emitting light of different colors. For example, the display device DD may include first pixels PX1 emitting light of a first color (e.g., blue light having a wavelength range of approximately 430 nm to 500 nm and having a peak wavelength in a range of 440 nm to 480 nm (e.g., approximately 450 nm to 460 nm)), second pixels PX2 emitting emit light of a second color (e.g., green light having a wavelength range of approximately 500 nm to 570 nm and having a peak wavelength in a range of 510 nm to 550 nm (e.g., approximately 520 nm to 530 nm)), and third pixels PX3 emitting light of a third color (e.g., red light having a wavelength range of approximately 610 nm to 680 nm and having a peak wavelength in a range of 610 nm to 650 nm (e.g., approximately 620 nm to 623 nm)). A primary color of light emitted from each of the pixels PX may be changed according to embodiments.

At least one first pixel PX1, at least one second pixel PX2, and at least one third pixel PX3 located adjacent to each other may constitute one pixel group PXG. For example, each of the pixel groups PXG may include one first pixel PX1, one second pixel PX2, and one third pixel PX3 as illustrated in FIG. 1, or may include two first pixels PX1, one second pixel PX2, and one third pixel PX3 as illustrated in FIG. 2. In addition, the type and/or number of pixels PX constituting each of the pixel groups PXG may be variously changed according to various embodiments. Various colors may be displayed in the pixel group PXG by individually controlling the emission luminance or the like of the first, second, and third pixels PX1, PX2, and PX3 constituting each of the pixel groups PXG.

Each of the pixels PX may include at least one light emitting element driven by a driving signal (e.g., a scan signal and a data signal) and/or a power voltage (e.g., a first power voltage and a second power voltage). The pixels PX may have a structure according to at least one of the embodiments to be described in more detail below. For example, the pixels PX may have a structure to which any one of the embodiments to be described below is applied, or may have a structure to which at least two embodiments are applied in combination.

According to some embodiments, the light emitting element of each of the pixels PX may include a pixel electrode provided individually corresponding to an emission area of the corresponding pixel PX, a common electrode facing the pixel electrode, and a light emitting stack interposed between the pixel electrode and the common electrode and including at least one light emitting layer. According to some embodiments, the light emitting stack may generate light of the same color (e.g., white light) in the emission areas of the pixels PX, and each color filter corresponding to the color of the light to be emitted from each of the pixels PX may be located on the light emitting elements of the pixels PX.

The pixels PX may have various shapes. For example, each of the pixels PX (or the emission area of the pixel PX) may have a quadrilateral shape as illustrated in FIG. 1 or may have a non-quadrilateral shape such as a hexagonal shape as illustrated in FIG. 2. In addition, each of the pixels PX may have various shapes including a circular shape or an elliptical shape.

The pixels PX may be arranged in the display area DA according to various arrangement structures. For example, in each pixel row extending along the first direction DR1 and each pixel column extending along the second direction DR2, the first pixels PX1, the second pixels PX2, and the third pixels PX3 may be arranged in a stripe shape. Alternatively, the first pixels PX1, the second pixels PX2, or the third pixels PX3 may be arranged along an oblique direction inclined with respect to the first and second directions DR1 and DR2 (e.g., a diagonal direction inclined with respect to the first and second directions DR1 and DR2 on the display surface of the display device DD) or the like. In addition, the arrangement structure of the pixels PX may be variously changed.

The non-display area NA may be arranged around the display area DA. Wires, embedded circuits, and/or pads connected to the pixels PX of the display area DA may be located in the non-display area NA.

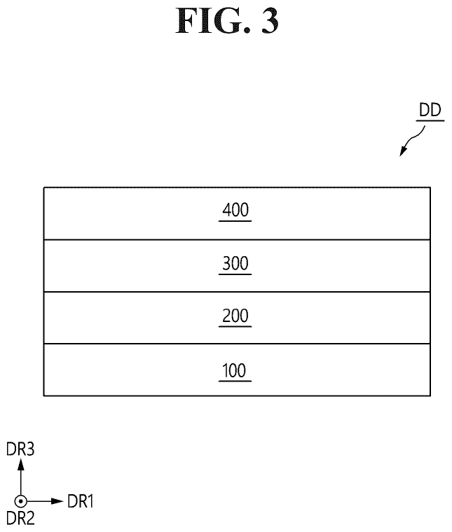

FIG. 3 is a cross-sectional view schematically illustrating a structure of the display device DD according to some embodiments.

Referring to FIG. 3 in addition to FIGS. 1 and 2, the display device DD may include a base member 100 (or a base layer), and a panel circuit layer 200, a light emitting element layer 300, and a color filter layer 400 sequentially arranged or provided on the base member 100. However, the structure of the display device DD is not limited thereto. For example, according to some embodiments, first, the light emitting element layer 300 may be located on one surface of the base member 100, and then the panel circuit layer 200 may be located on the light emitting element layer 300. According to some embodiments, the panel circuit layer 200 may not be provided in the display panel of the display device DD.

The base member 100 may include the substrate SUB (or film) that is rigid or flexible or may be the above-mentioned substrate SUB. According to some embodiments, the base member 100 may be one of a glass substrate, a quartz substrate, a glass ceramic substrate, a film substrate including a high molecular organic material, and a plastic substrate, but embodiments according to the present disclosure are not limited thereto.

The panel circuit layer 200 may include circuit elements and wires provided inside the display panel. For example, the panel circuit layer 200 may include circuit elements (e.g., transistors and capacitors) provided in the display area DA and constituting a pixel circuit of each of the pixels PX, and wires connected to the pixels PX.

The light emitting element layer 300 (also referred to as a “light source unit” or “light emitting element unit”) may include light emitting elements functioning as light sources for each of the pixels PX. For example, the light emitting element layer 300 may include a self-light emitting element provided or formed in the emission area of each pixel PX. According to some embodiments, the self-light emitting element may include at least one of an organic light emitting diode, a quantum dot light emitting diode, an inorganic micro light emitting diode (e.g., micro LED), or an inorganic nano light emitting diode (e.g., nano LED). According to some embodiments, the self-light emitting element may be a tandem type organic light emitting diode.

The color filter layer 400 may include color filters (e.g., color filters corresponding to the primary color of each pixel) that control transmission of light such that the pixels PX emit light corresponding to each primary color. For example, the color filter layer 400 may include first color filters located on the light emitting elements of the first pixels PX1 and selectively transmitting light of the first color, second color filters located on the light emitting elements of the second pixels PX2 and selectively transmitting light of the second color, and third color filters located on the light emitting elements of the third pixels PX3 and selectively transmitting light of the third color. Accordingly, the first pixels PX1, the second pixels PX2, and the third pixels PX3 may emit light of the first color, light of the second color, and light of the third color, respectively.

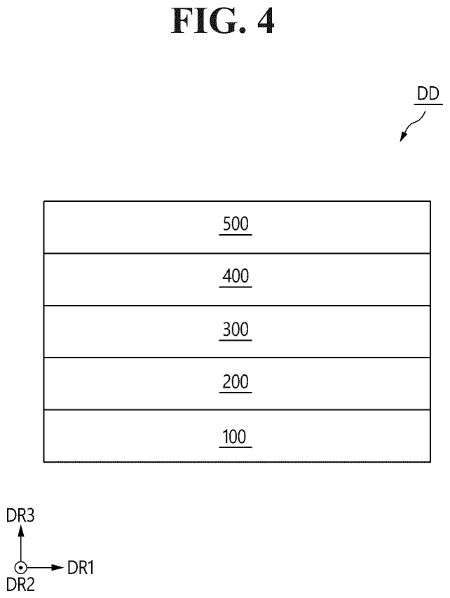

FIG. 4 is a cross-sectional view schematically illustrating a structure of the display device DD according to some embodiments.

Referring to FIG. 4 in addition to FIGS. 1 to 3, the display device DD may further include a protection member 500 (or passivation layer) located or provided on the color filter layer 400.

The protection member 500 may be a single layer or multilayer insulating layer, or a glass substrate or a plastic substrate, but is not limited thereto. The protection member 500 may be directly formed or provided on one surface of the base member 100 including the light emitting element layer 300 and the like, or may be provided separately from the base member 100 and be combined with the base member 100 through a sealing material and/or a filler and the like. When the protection member 500 is provided separately from the base member 100, the color filter layer 400 may be directly formed or provided on one surface of the base member 100 including the light emitting element layer 300 and the like, or may be located or provided on the light emitting element layer 300 through a bonding process after being formed or provided on the protection member 500 separately from the light emitting element layer 300.

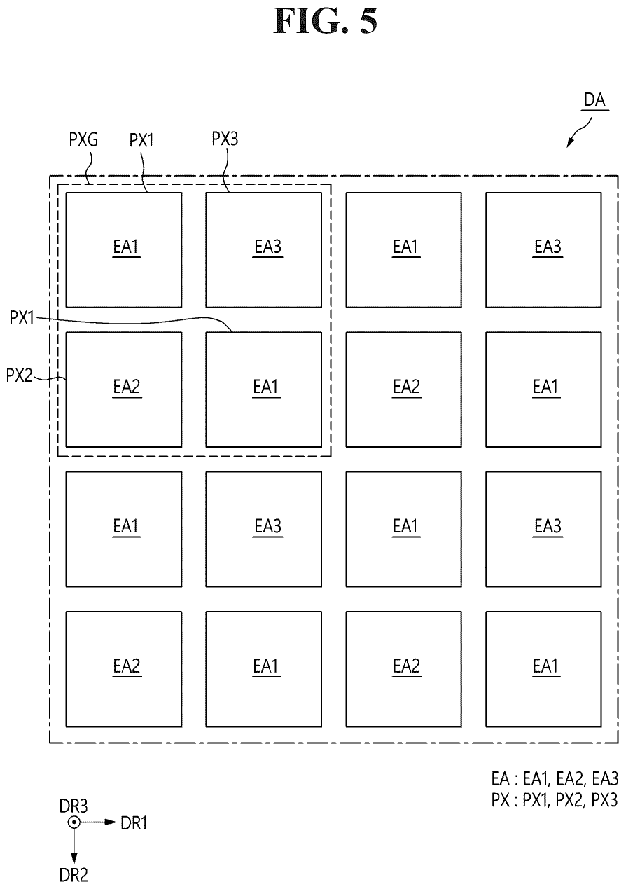

FIGS. 5 to 8 are plan views illustrating the display area DA of the display device DD according to the respective embodiments. For example, FIGS. 5 to 8 illustrate a part of the display area DA according to different embodiments in relation to the shape, size, and arrangement structure of the pixels PX. FIGS. 5 to 8 illustrate the positions and shapes of the pixels PX according to the respective embodiments based on the emission areas EA.

Referring to FIG. 5 in addition to FIGS. 1 to 4, the display area DA may include pixel areas including the respective emission areas EA. Each pixel area may include the emission area EA in which the light emitting element of the corresponding pixel PX is provided and/or located, and a pixel circuit area in which the circuit elements (e.g., transistors and a capacitor constituting each pixel circuit) of the corresponding pixel PX are provided and/or located. According to some embodiments, the emission area EA of each of the pixels PX may overlap the pixel circuit area of the corresponding pixel PX, but embodiments according to the present disclosure are not limited thereto.

The emission areas EA may be areas in which light generated by the light emitting element layer 300 passes through the color filter layer 400 and is emitted to the outside of the display device DD. The emission areas EA may be spaced apart from each other, and areas (e.g., areas between and/or around the emission areas EA) other than the emission areas EA in the display area DA may correspond to light blocking areas as non-emission areas.

Each of the emission areas EA may emit light of a color corresponding to the primary color of the corresponding pixel PX. For example, a first emission area EA1 of the first pixel PX1 may emit light of the first color, a second emission area EA2 of the second pixel PX2 may emit light of the second color, and a third emission area EA3 of the third pixel PX3 may emit light of the third color.

The pixels PX (or the emission areas EA of the pixels PX) may have an approximately quadrilateral shape and may include the emission areas EA having substantially similar or same sizes. For example, the first emission area EA1, the second emission area EA2, and the third emission area EA3 may have substantially similar or same shapes (e.g., quadrilateral shapes) and may have substantially similar or same sizes (e.g., areas).

According to some embodiments, each of the pixel groups PXG may include at least two pixels PX emitting light of the same color. For example, each of the pixel groups PXG may include two first pixels PX1 emitting light of the first color, one second pixel PX2 emitting light of the second color, and one third pixel PX3 emitting light of the third color. According to some embodiments, the type and/or number or the like of the pixels PX included in each of the pixel groups PXG may be determined in consideration of factors such as the luminous efficiency, lifespan, and/or white balance of the pixels PX. For example, by arranging two first pixels PX1 in each of the pixel groups PXG, the luminous efficiency and lifespan of the first pixels PX1 may be improved.

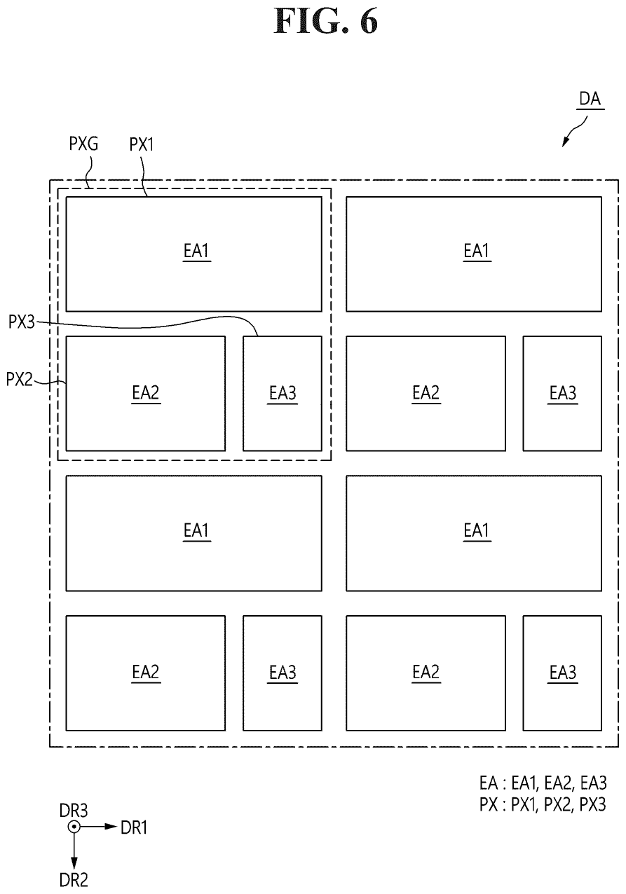

Referring to FIG. 6 in addition to FIGS. 1 to 5, at least two pixels PX among the first pixel PX1, the second pixel PX2, and the third pixel PX3 may include the emission areas EA having different sizes. For example, the first emission area EA1, the second emission area EA2, and the third emission area EA3 may have different sizes. For example, each of the pixel groups PXG may include one first pixel PX1, one second pixel PX2, and one third pixel PX3, and the first pixel PX1, the second pixel PX2, and the third pixel PX3 may include the emission areas EA having different sizes. For example, the first emission area EA1 may have a larger area than the second emission area EA2 and the third emission area EA3, and the third emission area EA3 may have a smaller area than the first emission area EA1 and the second emission area EA2. According to some embodiments, the size of the emission areas EA of the pixels PX may be differently designed in consideration of factors such as the luminous efficiency, lifespan, and/or white balance of the pixels PX.

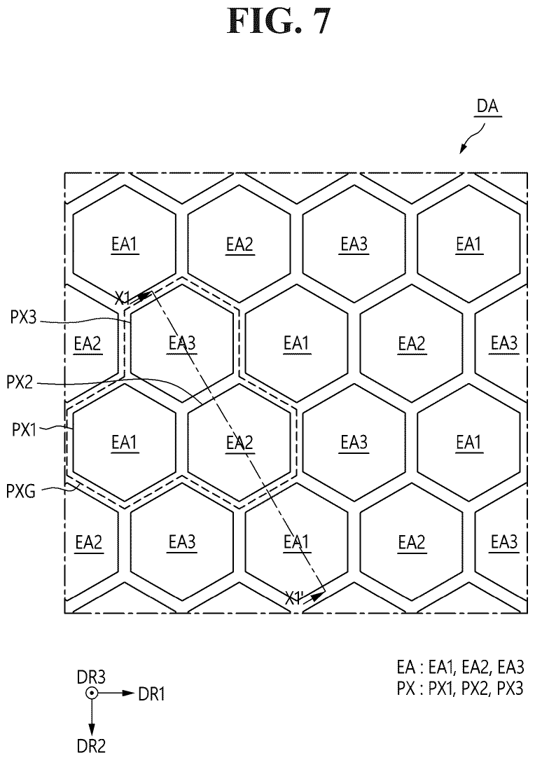

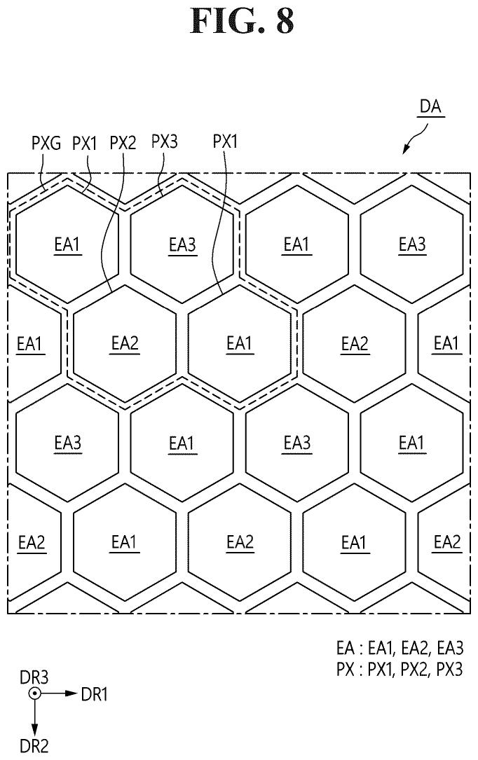

Referring to FIGS. 7 and 8 in addition to FIGS. 1 to 6, the pixels PX (or the emission areas EA of the pixels PX) may have an approximately hexagonal shape and may include the emission areas EA having substantially similar or same sizes. According to some embodiments, each of the pixel groups PXG may include the same number of first pixels PX1, second pixels PX2, and third pixels PX3. According to some embodiments, each of the pixel groups PXG may include different numbers of first pixels PX1, second pixels PX2, and/or third pixels PX3.

In addition to the above-described embodiments, the shape, size, ratio, number, and/or arrangement structure, or the like of the pixels PX may be variously changed.

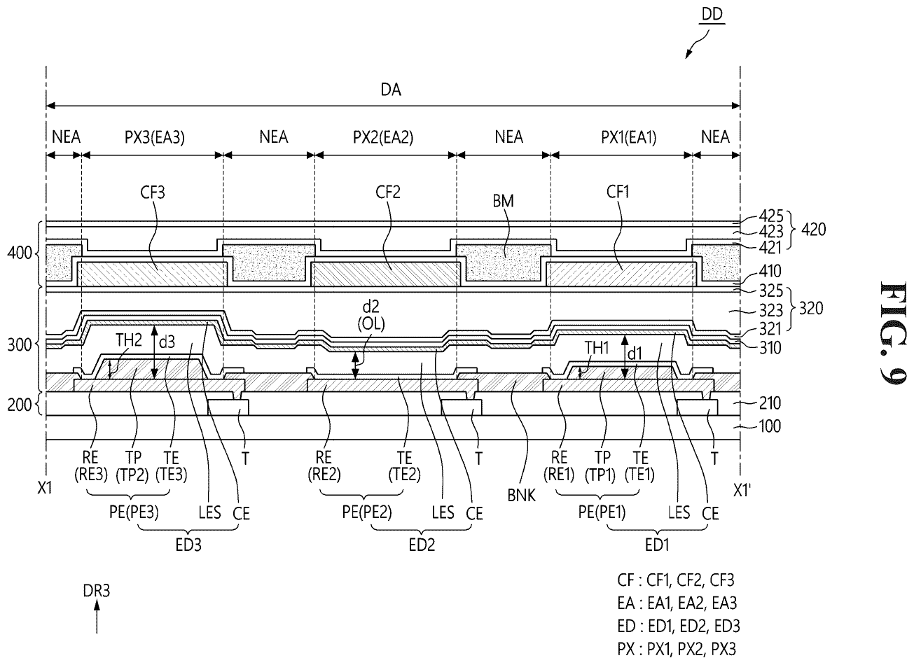

FIG. 9 is a plan view illustrating the display device DD according to some embodiments. For example, FIG. 9 illustrates a cross section of the display device DD corresponding to line X1-X1′ of FIG. 7 according to some embodiments.

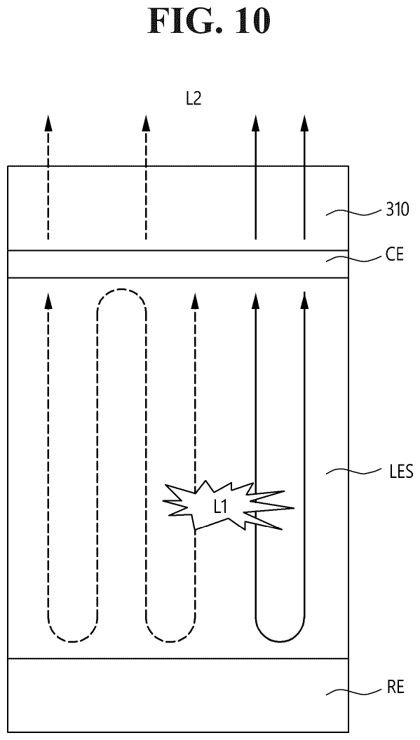

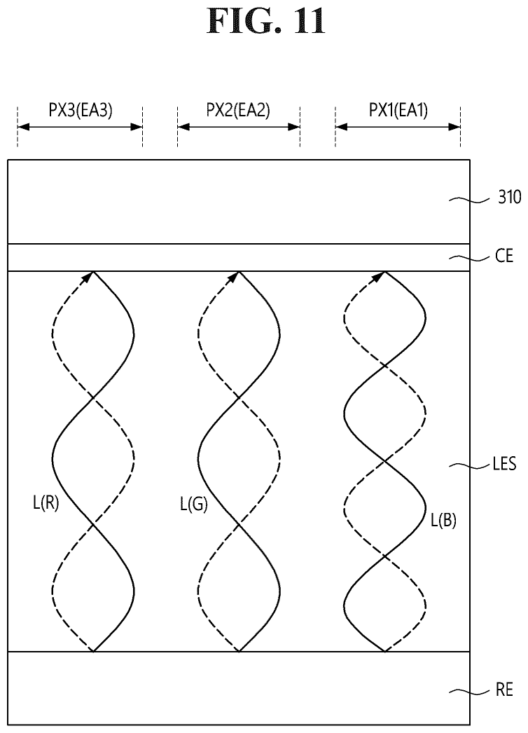

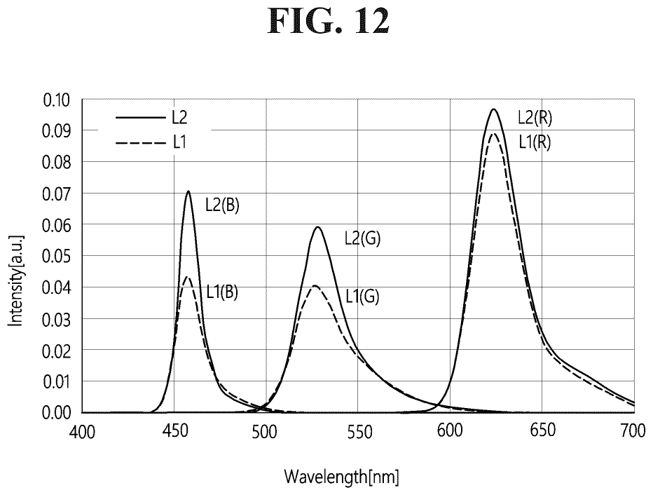

FIG. 10 is a cross-sectional view schematically illustrating a traveling path of light generated by a light emitting stack LES. FIG. 11 is a cross-sectional view schematically illustrating a resonance waveform of light generated between a reflective electrode RE and a common electrode CE. FIG. 12 is a graph illustrating the micro-cavity effect of light generated from a light emitting element ED.

Referring to FIGS. 9 to 12 in addition to FIGS. 1 to 8, the display device DD may include the base member 100, and the panel circuit layer 200, the light emitting element layer 300, and the color filter layer 400 sequentially located or provided on the base member 100. According to some embodiments, the display device DD may further include the protection member 500 (e.g., an insulating layer or an upper substrate) located or provided on the color filter layer 400 as illustrated in FIG. 4.

The base member 100 may include the rigid or flexible substrate SUB. According to some embodiments, the base member 100 may further include a separate layer provided on the substrate SUB, for example, a buffer layer or an insulating layer.

The display area DA may be defined in the base member 100, and in the display area DA, the emission areas EA of pixels PX and a non-emission area NEA around the emission areas EA may be defined. According to some embodiments, the display area DA may include the first emission areas EA1 of the first pixels PX1, the second emission areas EA2 of the second pixels PX2, and the third emission areas EA3 of the third pixels PX3, and the non-emission areas NEA surrounding the first emission areas EA1, the second emission areas EA2, and the third emission areas EA3.

The panel circuit layer 200 may be selectively located or provided on the base member 100. The panel circuit layer 200 may include circuit elements such as transistors T, wires, and the like. FIG. 9 schematically illustrates the transistors T connected to the light emitting elements ED of the pixels PX as an example of circuit elements provided to the panel circuit layer 200. According to some embodiments, each of the transistors T may be a thin film transistor including polysilicon or a thin film transistor including an oxide semiconductor.

An insulating layer 210 may be located or provided on circuit elements such as the transistors T and wires. According to some embodiments, the insulating layer 210 may be a planarization layer including an organic layer. For example, the insulating layer 210 may include acrylic resin, epoxy resin, imide resin, ester resin, or the like.

The light emitting element layer 300 including the light emitting elements ED may be located or provided on the panel circuit layer 200. The light emitting elements ED may be positioned in the emission areas EA, respectively, and each of the emission areas EA may include at least one light emitting element ED. For example, a first light emitting element ED1 may be located in the first emission area EA1, a second light emitting element ED2 may be located in the second emission area EA2, and a third light emitting element ED3 may be located in the third emission area EA3. According to some embodiments, the light emitting elements ED may be directly formed on one surface of the base member 100 on which the panel circuit layer 200 is formed.

Each of the light emitting elements ED may include a pixel electrode PE (also referred to as “first electrode”), the light emitting stack LES (also referred to as a “light emitting laminate” or “light emitting unit”), and the common electrode CE (also referred to as “second electrode”). Each of the light emitting elements ED may penetrate the insulating layer 210 of the panel circuit layer 200 and be connected to at least one circuit element (e.g., the transistor T) constituting the pixel circuit of the corresponding pixel PX.

According to some embodiments, the pixel electrode PE, the light emitting stack LES, and the common electrode CE may be sequentially located on the insulating layer 210 of the panel circuit layer 200. The pixel electrode PE and the common electrode CE may face each other, and the light emitting stack LES may be interposed between the pixel electrode PE and the common electrode CE.

One of the pixel electrode PE and the common electrode CE may be an anode electrode, and the other one thereof may be a cathode electrode. For example, the pixel electrode PE may be an anode electrode, and the common electrode CE may be a cathode electrode.

The pixel electrode PE may be a separate type electrode that is individually located and/or formed to correspond to each of the pixels PX and/or the emission areas EA. For example, the first light emitting element ED1 may include a first pixel electrode PE1 located in the first emission area EA1, and the second light emitting element ED2 may include a second pixel electrode PE2 located in the second emission area EA2, and the third light emitting element ED3 may include a third pixel electrode PE3 located in the third emission area EA3. The first pixel electrode PE1, the second pixel electrode PE2, and the third pixel electrode PE3 may be spaced apart from each other.

According to some embodiments, the light emitting stack LES and the common electrode CE may be commonly and/or continuously formed in the pixels PX and/or the emission areas EA, and may be a common layer shared by the light emitting elements ED. For example, the light emitting stack LES and the common electrode CE may be arranged or formed entirely over the display area DA, and each of the light emitting elements ED may include a part of the light emitting stack LES and the common electrode CE. For example, the light emitting stack LES and the common electrode CE may be located on the pixel electrodes PE of the light emitting elements ED and may be continuously formed entirely over the display area DA.

According to some embodiments, the pixel electrode PE may be a reflective type electrode including the reflective electrode RE, and the common electrode CE may be a semi-transmissive type electrode. Part of the light generated by each of the light emitting elements ED may directly pass through the common electrode CE and be emitted in the front direction (e.g., in the third direction DR3) of the display device DD, and the other part of the light may pass through the common electrode CE after being reflected by the reflective electrode RE or the like and be emitted in the front direction of the display device DD. For example, as indicated by a solid line arrow in FIG. 10, part of a first light L1 generated in at least one light emitting layer included in the light emitting stack LES may directly pass through the common electrode CE, and the other part may pass through the common electrode CE after being reflected by the reflective electrode RE or the like.

Each of the light emitting elements ED may be formed to have a micro-cavity (or thin film cavity) structure. For example, according to the position of at least one light emitting layer included in the light emitting stack LES and the distance between the reflective electrode RE and the common electrode CE, light of a specific wavelength range included in the first light L1 (e.g., red light, green light, and/or blue light) may be amplified by constructive interference. For example, as illustrated by a dotted line arrow in FIG. 10, the intensity of light of a specific wavelength range included in the first light L1 generated in at least one light emitting layer included in the light emitting stack LES may be amplified by the micro-cavity effect generated inside the light emitting stack LES, and then the light may pass through the common electrode CE.

According to some embodiments, the pixel electrode PE may include the reflective electrode RE and a light transmitting electrode TE located on the reflective electrode RE. For example, the first pixel electrode PE1 may include a first reflective electrode RE1 located in the first emission area EA1 and a first light transmitting electrode TE1 located on the first reflective electrode RE1 and connected (e.g., electrically connected) to the first reflective electrode RE1. The second pixel electrode PE2 may include a second reflective electrode RE2 located in the second emission area EA2 and a second light transmitting electrode TE2 located on the second reflective electrode RE2 and connected to the second reflective electrode RE2. The third pixel electrode PE3 may include a third reflective electrode RE3 located in the third emission area EA3 and a third light transmitting electrode TE3 located on the third reflective electrode RE3 and connected to the third reflective electrode RE3.

According to some embodiments, the reflective electrodes RE may include a metal layer containing metal such as silver (Ag), magnesium (Mg), aluminum (AI), platinum (Pt), palladium (Pd), gold (Au), nickel (Ni), neodymium (Nd), iridium (Ir), chromium (Cr) or a compound thereof. According to some embodiments, the reflective electrodes RE may further include a metal oxide layer (e.g., a transparent conductive oxide layer) positioned above and/or below the metal layer. For example, each of the reflective electrodes RE may have a double layer structure of ITO/Ag, Ag/ITO, ITO/Mg, or ITO/MgF, or a triple layer structure such as ITO/Ag/ITO.

The light transmitting electrodes TE may include a transparent conductive material. For example, the light transmitting electrodes TE may include transparent conductive oxide (TCO). For example, the light transmitting electrodes TE may include at least one material of indium tin oxide (ITO), indium zinc oxide (IZO), indium gallium oxide (IGO), aluminum zinc oxide (AZO), zinc oxide (ZnO), indium oxide (In₂O₃), indium tin zinc oxide (ITZO), tungsten oxide (WₓOₓ), titanium oxide (TiO₂), or magnesium oxide (MgO), or another transparent conductive material. According to some embodiments, each of the light transmitting electrodes TE may have a thickness in a range from approximately 70 Å to 100 Å, but the embodiments according to the present disclosure are not limited thereto.

According to some embodiments, at least one of the first pixel electrode PE1, the second pixel electrode PE2, or the third pixel electrode PE3 may further include a light transmitting pattern TP (also referred to as “light auxiliary layer”) located between the reflective electrode RE and the light transmitting electrode TE. For example, the first pixel electrode PE1 may further include a first light transmitting pattern TP1 located on a part of the first reflective electrode RE1, and the third pixel electrode PE3 may further include a second light transmitting pattern TP2 located on a part of the third reflective electrode RE3. In this case, the first light transmitting electrode TE1 may be located on the first reflective electrode RE1 and the first light transmitting pattern TP1, and the third light transmitting electrode TE3 may be located on the third reflective electrode RE3 and the second light transmitting pattern TP2.

The height of the light transmitting electrode TE located on the light transmitting pattern TP may be changed by the light transmitting pattern TP. For example, the pixel electrode PE including the light transmitting pattern TP (e.g., the first pixel electrode PE1 and the third pixel electrode PE3) may have a greater thickness and/or height corresponding to the thickness (or height) of the light transmitting pattern TP than the pixel electrode PE not including the light transmitting pattern TP (e.g., the second pixel electrode PE2). Accordingly, the heights of the light emitting stack LES and the common electrode CE may increase in the emission area EA (e.g., the first emission area EA1 and the third emission area EA3) in which the light transmitting pattern TP is located. When the height of the common electrode CE increases, a distance between the reflective electrode RE and the common electrode CE may increase. Accordingly, an optical length and a reflection distance between the reflective electrode RE and the common electrode CE may increase.

According to some embodiments, the distance between the reflective electrode RE and the common electrode CE may be differently adjusted for each pixel X to increase and/or optimize the micro-cavity effect with respect to light to be emitted from each of the pixels PX according to the wavelength of the light, the corresponding resonance distance and/or resonance order, or the like. For example, in order to appropriately amplify light of the first color, light of the second color, and light of the third color in the first emission area EA1, the second emission area EA2, and the third emission area EA3, respectively, the distance between the reflective electrode RE and the common electrode CE for each pixel PX may be set and/or adjusted to a first distance d1 (or a first reflection distance), a second distance d2 (or a second reflection distance), and a third distance d3 (or a third reflection distance), by using the light transmitting pattern TP. For example, each of the light transmitting patterns TP may have a thickness corresponding to a compensation distance needed to adjust the distance between the reflective electrode RE and the common electrode CE according to the N^{th} (N is a natural number) order resonance distance of light to be emitted from each of the emission areas EA.

According to some embodiments, the distance between the reflective electrode RE and the common electrode CE in each of the emission areas EA may correspond to the resonance distance of light emitted through the corresponding emission area EA. For example, the first distance d1 between the reflective electrode RE and the common electrode CE in the first emission area EA1 may correspond to the resonance distance (e.g., the N^{th} resonance distance of light of the first color) of light of the first color emitted through the first emission area EA1. The second distance d2 between the reflective electrode RE and the common electrode CE in the second emission area EA2 may correspond to the resonance distance of light of the second color emitted through the second emission area EA2. The third distance d3 between the reflective electrode RE and the common electrode CE in the third emission area EA3 may correspond to the resonance distance of light of the third color emitted through the third emission area EA3.

According to some embodiments, the resonance order with respect to light of a wavelength range to be amplified by each of the pixels PX may be determined in consideration of the wavelength and/or resonance distance of light to be emitted from each of the pixels PX, the structure and/or thickness range of the light emitting stack LES, or the like. For example, as illustrated in FIG. 11, in the first emission area EA1, the distance between the reflective electrode RE and the common electrode CE may be set to the first distance d1 according to a distance (e.g., a distance in which blue light L(B) having a peak wavelength of approximately 460 nm may exhibit the fourth order resonance, that is, a distance corresponding to four times the first order resonance distance of the blue light L(B)) in which light of the first color may exhibit the fourth order resonance, and the first light transmitting pattern TP1 may be formed with a first thickness TH1 such that the distance between the reflective electrode RE and the common electrode CE in the first emission area EA1 is set to the first distance d1.

According to some embodiments, when the light emitting stack LES includes a light emitting layer of the first color that generates light of the first color, the light emitting layer of the first color may be located at a height (or a height close thereto) at which a micro-cavity effect of light of the first color may be increased and/or optimized in the light emitting stack LES. Accordingly, light efficiency of the first pixel PX1 may be improved.

According to some embodiments, in the second emission area EA2, the distance between the reflective electrode RE and the common electrode CE may be set to the second distance d2 according to a distance (e.g., a distance in which green light L(G) having a peak wavelength of approximately 520 nm may exhibit the third order resonance, that is, a distance corresponding to three times the first order resonance distance of the green light L(G)) in which light of the second color may exhibit the third order resonance. For example, according to an optical length OL corresponding to the resonance distance and the resonance order of light of the second color, the thickness of the light emitting stack LES may be set to a value (e.g., a value obtained by subtracting the thickness of the second light transmitting electrode TE2 from the second distance d2) corresponding to the second distance d2.

According to some embodiments, when the light emitting stack LES includes a light emitting layer of the second color that generates light of the second color, the light emitting layer of the second color may be located at a height (or a height close thereto) at which a micro-cavity effect of light of the second color may be increased and/or optimized in the light emitting stack LES. Accordingly, light efficiency of the second pixel PX2 may be improved.

According to some embodiments, in the third emission area EA3, the distance between the reflective electrode RE and the common electrode CE may be set to the third distance d3 according to a distance (e.g., a distance in which red light L(R) having a peak wavelength of approximately 623 nm may exhibit the third order resonance, that is, a distance corresponding to three times the first order resonance distance of the red light L(R)) in which light of the third color may exhibit the third order resonance, and the second light transmitting pattern TP2 may be formed with a second thickness TH2 such that the distance between the reflective electrode RE and the common electrode CE in the third emission area EA3 is set to the third distance d3. According to some embodiments, when the light emitting stack LES includes a light emitting layer of the third color that generates light of the third color, the light emitting layer of the third color may be located at a height (or a height close thereto) at which a micro-cavity effect of light of the third color may be increased and/or optimized in the light emitting stack LES. Accordingly, light efficiency of the third pixel PX3 may be improved.

According to some embodiments, the distance (e.g., the reflection distance and/or the N^{th} resonance distance) between the reflective electrode RE and the common electrode CE in the emission area EA including the light transmitting pattern TP may be greater than the distance between the reflective electrode RE and the common electrode CE in the emission area EA not including the light transmitting pattern TP. For example, the distances (e.g., the first distance d1 and the third distance d3 respectively) between the reflective electrode RE and the common electrode CE in the first emission area EA1 and the third emission area EA3 including the first light transmitting pattern TP1 and the second light transmitting pattern TP2, respectively may be greater than the second distance d2 between the reflective electrode RE and the common electrode CE in the second emission area EA2 not including the light transmitting pattern TP.

According to some embodiments, the thickness of the light emitting stack LES may be set based on the pixel PX (e.g., the second pixel PX2) having the shortest optical length corresponding to the resonance distance and the resonance order corresponding to the wavelength (e.g., peak wavelength) of light to be emitted from each of the pixels PX, and with respect to the remaining pixels PX (e.g., the first pixel PX1 and the third pixel PX3), the optical length may be compensated according to the resonance distance and the resonance order of light to be emitted from the pixels PX by respectively using the light transmitting patterns TP. According to some embodiments, the light transmitting patterns TP may include the same insulating material, may be formed at the same time, and may have a thickness corresponding to light emitted from each of the pixels PX.

According to some embodiments, the light transmitting patterns TP may have a thickness in consideration of the resonance efficiency of light in a specific wavelength range, and may have a thickness that may adequately compensate for an optical length for each pixel PX corresponding to light in a wavelength range to be emitted from each of the pixels PX. For example, the light transmitting patterns TP may have a thickness in a range from approximately 300 Å to 850 Å to prevent resonance degradation of blue light. For example, the first light transmitting pattern TP1 may be formed to have a thickness of approximately 300 Å to 450 Å to compensate for a difference between an optimal optical length in the first pixel PX1 and an optimal optical length in the second pixel PX2, and the second light transmitting pattern TP2 may be formed to have a thickness of approximately 450 Å to 850 Å to compensate for a difference between an optimal optical length in the third pixel PX3 and an optimal optical length in the second pixel PX2. Accordingly, the optical length of the pixels PX may be appropriately and/or easily compensated.

As described above, the light efficiency of the pixels PX may be increased by compensating for the optical resonance distance (or the corresponding optical length) according to a wavelength of light emitted from each of the emission areas EA by using the light transmitting pattern TP. For example, as illustrated in FIG. 12, the first light L1(B), L1(G), and L1(R) in the wavelength range of a first color (e.g., blue (B)), a second color (e.g., green (G)), and a third color (e.g., red (R)) may be amplified into the second light L2(B), L2(G), and L2(R) having greater intensity in the wavelength range of the first color, second color, and third color.

According to some embodiments, the light transmitting pattern TP may be an insulating pattern including an insulating material. For example, the light transmitting pattern TP may be an insulating pattern including the same insulating material as the bank pattern BNK, and the light transmitting pattern TP and the bank pattern BNK may be located and/or formed on the same layer. For example, by depositing an insulating layer including a light transmittance insulating material entirely on one surface of the base member 100 on which the panel circuit layer 200 and the pixel electrodes PE are formed, and then patterning the insulating layer by a photoresist process or the like, each of the light transmitting patterns TP and the bank pattern BNK may be separated from each other and simultaneously (or concurrently) formed. Accordingly, the manufacturing process of the display device DD may be simplified and manufacturing efficiency may be increased.

According to some embodiments, when at least two light transmitting patterns TP and/or bank patterns BNK have different thicknesses, two or more etching processes may be performed or one etching process using a halftone mask or the like may be performed, so that at least two light transmitting patterns TP and/or bank patterns BNK may be formed to have different thicknesses. A method of forming the light transmitting patterns TP and the bank pattern BNK is not limited and may be variously changed according to embodiments.

According to some embodiments, the light transmitting pattern TP and the bank pattern BNK may be formed of a transparent insulating material that may be easily formed to have a desired thickness. For example, the light transmitting pattern TP and the bank pattern BNK may be formed of a silicon-based inorganic insulating material (e.g., silicon nitride, silicon oxide, or silicon oxynitride) or another inorganic insulating material.

According to some embodiments, the light transmitting pattern TP may be a separation type pattern locally located on a part of each of the reflective electrodes RE, and may expose the remaining portion of the reflective electrode RE. The light transmitting electrode TE of the pixel electrode PE including the light transmitting pattern TP may be located on the reflective electrode RE and the light transmitting pattern TP, and may be connected to the reflective electrode RE in a portion on which the light transmitting pattern TP is not located.

The bank pattern BNK (or a pixel defining layer) may be located between the pixel electrodes PE. The bank pattern BNK may define the emission areas EA and the non-emission area NEA. The bank pattern BNK may be positioned in the non-emission area NEA, and may include openings exposing the reflective electrodes RE corresponding to the emission areas EA, respectively. For example, the bank pattern BNK surrounds the emission areas EA, and at least a portion of the bank pattern BNK may be positioned between the emission areas EA. According to some embodiments, the bank pattern BNK may be a mesh type pattern including openings exposing the emission areas EA of the pixels PX. According to some embodiments, the bank pattern BNK may overlap the light blocking member BM.

According to some embodiments, the bank pattern BNK may overlap a part of the pixel electrodes PE. For example, the bank pattern BNK may overlap the edges of the pixel electrodes PE extending into the non-emission area NEA. According to some embodiments, the bank pattern BNK may be formed together with the light transmitting patterns TP after the reflective electrodes RE are formed, and a part of the bank pattern BNK may overlap the reflective electrodes RE. The bank pattern BNK may be formed to be spaced apart from the light transmitting patterns TP. Accordingly, leakage or propagation of light in the lateral direction of the pixels PX may be prevented, and color mixing between the pixels PX may be prevented.

The light emitting stack LES including at least one light emitting layer may be located on the pixel electrodes PE and the bank pattern BNK. According to some embodiments, the light emitting stack LES may be a common layer continuously formed over the emission areas EA and the non-emission area NEA. For example, each layer of the light emitting stack LES may be formed entirely in the display area DA.

According to some embodiments, the light emitting stack LES may include a first light emitting layer emitting light of the first color, a second light emitting layer emitting light of the second color, and a third light emitting layer emitting light of the third color, and thus may emit light of a white color. According to some embodiments, the light emitting stack LES may have a tandem structure.

The common electrode CE may be located on the light emitting stack LES. According to some embodiments, the common electrode CE may be a semi-transmissive type thin film electrode including metal. For example, the common electrode CE may include silver (Ag), magnesium (Mg), copper (Cu), aluminum (Al), lithium (Li), calcium (Ca), ytterbium (Yb), platinum (Pt), palladium (Pd), gold (Au), nickel (Ni), neodymium (Nd), iridium (Ir), chromium (Cr), molybdenum (Mo), titanium (Ti) or a compound or mixture thereof, for example a mixture of silver (Ag) and magnesium (Mg), and may have a semi-transmissive property by having a thickness of approximately several tens to hundreds of angstroms. For example, the common electrode CE may be a semi-transmissive type thin film electrode having a light transmittance in a range from approximately 40% to 60%, but the light transmittance or the like of the common electrode CE is not limited thereto.

An encapsulation layer 320 may be located or provided on the common electrode CE. The encapsulation layer 320 may be commonly located in the emission areas EA and the non-emission areas NEA.

According to some embodiments, the encapsulation layer 320 may include a first encapsulation layer 321, a second encapsulation layer 323, and a third encapsulation layer 325 sequentially stacked on the common electrode CE. In some embodiments, each of the first encapsulation layer 321 and the third encapsulation layer 325 may be an inorganic layer formed of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, lithium fluoride or the like.

According to some embodiments, the second encapsulation layer 323 may be an organic layer formed of acrylic resin, methacrylic resin, polyisoprene, vinyl resin, epoxy resin, urethane resin, cellulose resin, perylene resin or the like. The structure and material of the encapsulation layer 320 may be changed according to embodiments.

The encapsulation layer 320 may constitute the light emitting element layer 300 together with the light emitting elements ED. Alternatively, the encapsulation layer 320 may be regarded as a separate component from the light emitting element layer 300.

The color filter layer 400 may be located or provided on the light emitting element layer 300. The color filter layer 400 may include color filters CF corresponding to the colors of the pixels PX. For example, the color filter layer 400 may include a first color filter CF1 located in the first emission area EA1 of the first pixel PX1, a second color filter CF2 located in the second emission area EA2 of the second pixel PX2, and a third color filter CF3 located in the third emission area EA3 of the third pixel PX3. Each of the color filters CF may be provided on the encapsulation layer 320 to overlap the light emitting element ED of the corresponding pixel PX. For example, the first color filter CF1 may be located on the common electrode CE to correspond to the first emission area EA1, the second color filter CF2 may be located on the common electrode CE to correspond to the second emission area EA2, and the third color filter CF3 may be located on the common electrode CE to correspond to the third emission area EA3.

The first color filter CF1 may selectively transmit light of the first color. For example, the first color filter CF1 may transmit light of the first color (e.g., blue light) and may block or absorb light of other colors (e.g., red light and green light). According to some embodiments, the first color filter CF1 may be a blue color filter and may include a blue colorant such as a blue dye or a blue pigment.

Light (e.g., white light) emitted from each of the first light emitting elements ED1 may pass through the first color filter CF1 and be emitted to the outside. Accordingly, light of the first color (e.g., blue light) may be emitted from the first emission area EA1.

The second color filter CF2 may selectively transmit light of the second color. For example, the second color filter CF2 may transmit light of the second color (e.g., green light), and block or absorb light of the first color (e.g., blue light) and light of the third color (e.g., red light). According to some embodiments, the second color filter CF2 may be a green color filter and may include a green colorant.

Light (e.g., white light) emitted from each of the second light emitting elements ED2 may pass through the second color filter CF2 and be emitted to the outside. Accordingly, light of the second color (e.g., green light) may be emitted from the second emission area EA2.

The third color filter CF3 may selectively transmit light of the third color. For example, the third color filter CF3 may selectively transmit light of the third color (e.g., red light), and block or absorb light of the first color (e.g., blue light) and light of the second color (e.g., green light). According to some embodiments, the third color filter CF3 may be a red color filter and may include a red colorant.

Light (e.g., white light) emitted from each of the third light emitting elements ED3 may pass through the third color filter CF3 and be emitted to the outside. Accordingly, light of the third color (e.g., red light) may be emitted from the third emission area EA3.

According to some embodiments, the first, second, and third color filters CF1, CF2, and CF3 may be formed to be separated from each other in the emission areas EA of the pixels PX, and the light blocking member BM may be located among the first, second, and third color filters CF1, CF2, and CF3. According to some embodiments, the first, second, and third color filters CF1, CF2, and CF3 may overlap each other in the non-emission area NEA to function as a light blocking pattern.

The light blocking member BM may be positioned in the non-emission area NEA to block transmission of light. The light blocking member BM may be positioned between and around the emission areas EA to surround the emission areas EA, and thus may prevent color mixing between the emission areas EA. According to some embodiments, the light blocking member BM may include an organic light blocking material.

The color filter layer 400 may further include at least one capping layer. For example, the color filter layer 400 may include a first capping layer 410 covering the color filters CF, and a second capping layer 420 covering an upper portion of one surface of the base member 100 in which the color filters CF, the first capping layer 410, and the light blocking member BM are located.

The first capping layer 410 may be located or provided entirely over the display area DA including the first emission area EA1, the second emission area EA2, and the third emission area EA3. The first capping layer 410 may be a capping layer that protects the color filters CF and may be made of an inorganic material. For example, the first capping layer 410 may contain silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or the like.

The second capping layer 420 may be located entirely on the display area DA to cover the color filters CF, the first capping layer 410 and the light blocking member BM. According to some embodiments, the second capping layer 420 may have a multilayer structure including a first inorganic layer 421, an organic layer 423, and a second inorganic layer 425.

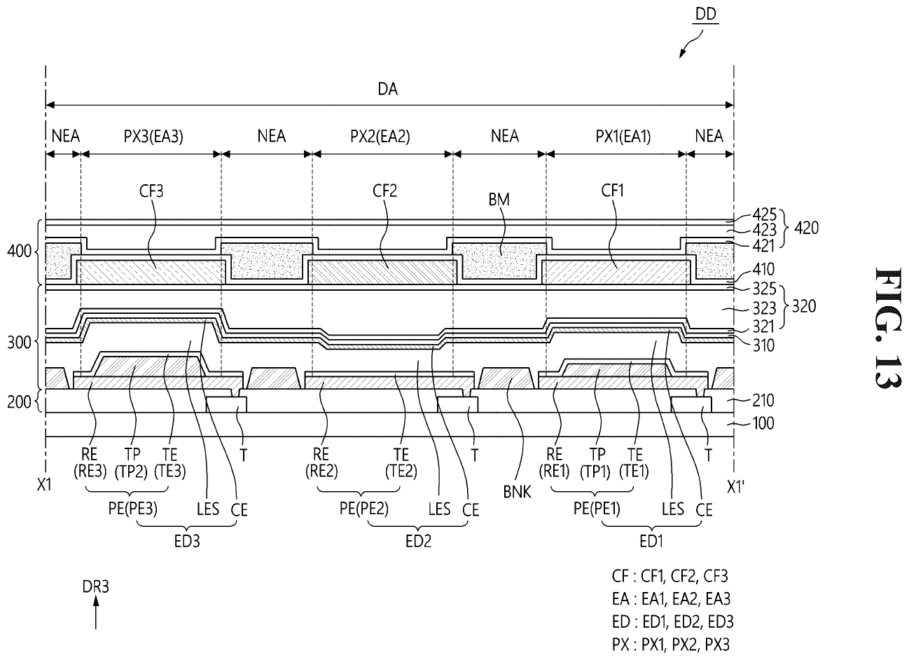

FIGS. 13 to 16 are cross-sectional views illustrating the display device DD according to respective embodiments. For example, FIGS. 13 to 16 illustrate embodiments of cross sections of the display device DD corresponding to line X1-X1′ of FIG. 7 and illustrate different modified embodiments of the embodiments of FIG. 9.

Referring to FIG. 13 in addition to FIGS. 1 to 9, the bank pattern BNK may not overlap the reflective electrodes RE, and may be spaced apart from the pixel electrodes PE including the reflective electrodes RE. For example, the bank pattern BNK may be located in the non-emission area NEA between the pixels PX to be spaced apart from the pixel electrodes PE.

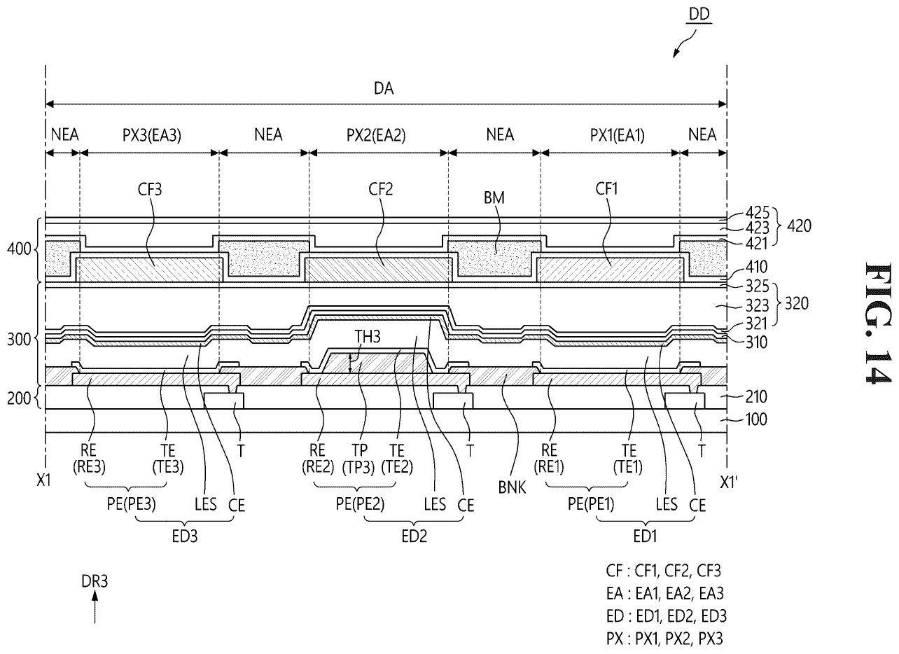

Referring to FIG. 14 in addition to FIGS. 1 to 9, the light transmitting patterns TP may be respectively located in the pixels PX of any one group among the first pixels PX1, the second pixels PX2, and the third pixels PX3, and the light transmitting patterns TP may not be located in the remaining pixels PX. For example, the second pixel electrode PE2 of the second light emitting element ED2 may include a third light transmitting pattern TP3 having a third thickness TH3, and the first light emitting element ED1 and the third light emitting element ED3 may not include the light transmitting pattern TP.

In this case, the light emitting stack LES having a structure and/or thickness conforming to the wavelength range of light of the first color and/or light of the third color and the corresponding resonance distance (or the optical length corresponding to the resonance distance and the resonance order) may be formed, and in the second emission area EA2, the optical length may be compensated to appropriately amplify light of the second color by using the third light transmitting pattern TP3.

The third light transmitting pattern TP3 may be located on a part of the second reflective electrode RE2 and may include the same insulating material as the bank pattern BNK. The second light transmitting electrode TE2 may be located on the second reflective electrode RE2 and the third light transmitting pattern TP3 and may be connected to the second reflective electrode RE2.

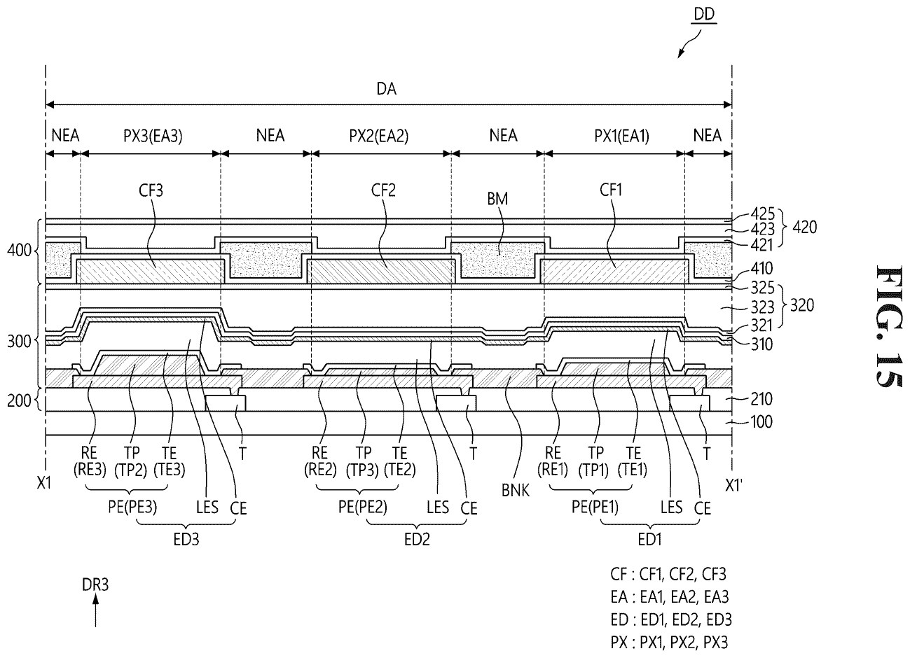

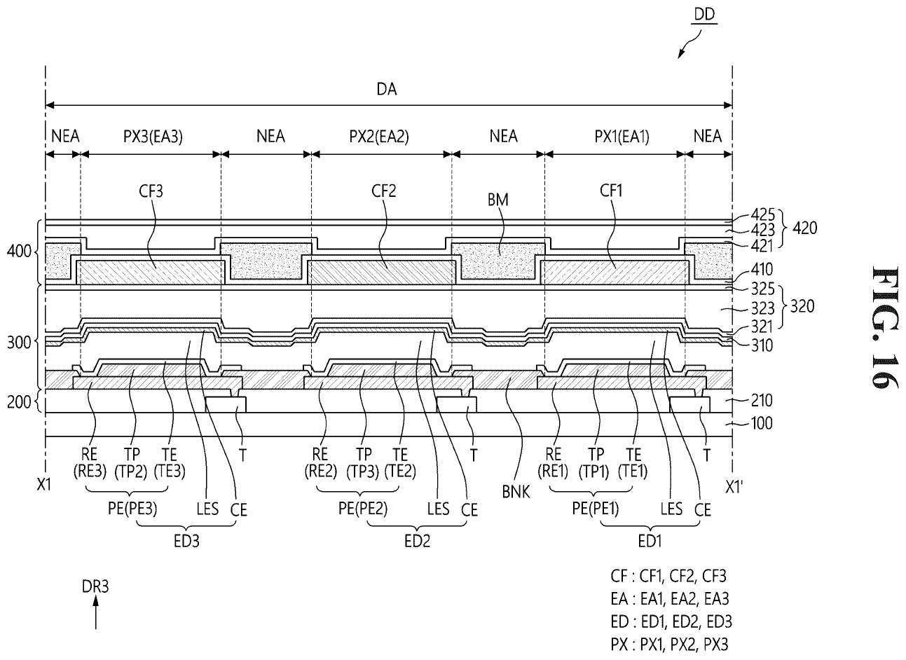

Referring to FIGS. 15 and 16 in addition to FIGS. 1 to 9, the first pixels PX1, the second pixels PX2, and the third pixels PX3 may include the light transmitting patterns TP, respectively and may have optical lengths appropriately compensated by the light transmitting patterns TP. According to some embodiments, at least two groups of pixels PX among the first pixels PX1, the second pixels PX2, and the third pixels PX3 may include the light transmitting patterns TP having different thicknesses. For example, as illustrated in FIG. 15, the first pixels PX1, the second pixels PX2, and the third pixels PX3 may include the light transmitting patterns TP having different thicknesses. For example, the first light transmitting patterns TP1, the third light transmitting patterns TP3, and the second light transmitting patterns TP2 provided to the first pixels PX1, the second pixels PX2, and the third pixels PX3, respectively may have differentially set thicknesses to conform to the optical length corresponding to each of the emission areas EA. The first light transmitting patterns TP1, the third light transmitting patterns TP3, and the second light transmitting patterns TP2 may be formed on the same layer by using the same material as the bank pattern BNK.

According to some embodiments, the first pixels PX1, the second pixels PX2, and the third pixels PX3 may include the light transmitting patterns TP having the same thickness as illustrated in FIG. 16. For example, the light transmitting patterns TP of the first pixels PX1, the second pixels PX2, and the third pixels PX3 may have thicknesses that may be set by comprehensively considering an optical length in each of the emission areas EA according to the formation of the light emitting stack LES, and the light efficiency of the first pixels PX1, the second pixels PX2, and the third pixels PX3.

As described above, the structure of the pixels PX including the light transmitting patterns TP and the display device DD may be variously changed according to embodiments.

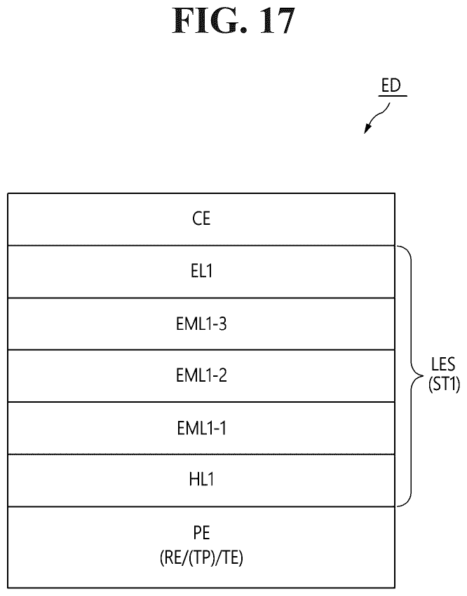

FIGS. 17 to 23 are cross-sectional views schematically showing the structure of the light emitting element ED according to respective embodiments. For example, FIGS. 17 to 23 illustrate different embodiments in relation to the light emitting stack LES included in the light emitting element ED, and overlapping descriptions related to similar or same elements and/or configurations in the embodiments will be omitted.

Referring to FIG. 17 in addition to FIGS. 1 to 16, the light emitting element ED may include the pixel electrode PE and the common electrode CE facing each other, and the light emitting stack LES provided between the pixel electrode PE and the common electrode CE. The light emitting element ED located in the emission area EA of at least one pixel PX may include the light transmitting pattern TP. For example, each of the light emitting elements ED may include the reflective electrode RE and the light transmitting electrode TE, and may include or may not include the light transmitting pattern TP provided between the reflective electrode RE and the light transmitting electrode TE.

The light emitting stack LES may include a high molecular or a low molecular organic material that emits light of a color (e.g., a set or predetermined color). In addition to various organic materials, the light emitting stack LES may further include metal-containing compounds such as organometallic compounds, inorganic materials such as quantum dots, or the like.

The light emitting stack LES may include at least one light emitting layer. For example, the light emitting stack LES may include a first light emitting layer EML1-1, and may selectively further include at least one of a second light emitting layer EML1-2 or a third light emitting layer EML1-3 overlapping the first light emitting layer EML1-1. For example, the light emitting stack LES may include the first light emitting layer EML1-1 generating light of the first color, the second light emitting layer EML1-2 generating light of the second color, and the third light emitting layer EML1-3 generating light of the third color, and thus may emit light of a white color.

Each light emitting layer may include a host and a dopant. The light emitting layer may be formed by using a phosphorescent or fluorescent light emitting material as a dopant in a host material. A material of the host is not particularly limited as long as it is generally used. For example, tris(8-hydroxyquinolinato)aluminium (Alq3), 4,4′-bis(N-carbazolyl)-1,1′-biphenyl (CBP), poly(n-vinylcarbazole) (PVK), 9,10-di(naphthalene-2-yl)anthracene (ADN), 4,4′,4″-Tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), or 2-methyl-9,10-bis(naphthalen-2-yl)anthracene (MADN), and the like may be used. The color of light emitted from the light emitting layer may be determined by a combination of a host material and a dopant material.

According to some embodiments, a blue light emitting layer emitting blue light may include a fluorescent material containing any one selected from the group consisting of spiro-DPVBi, spiro-6P, distyryl-benzene (DSB), distyryl-arylene (DSA), a polyfluorene (PFO)-based polymer, and a poly(p-phenylene vinylene) (PPV)-based polymer. A dopant material included in the blue light emitting layer may be selected from, for example, a metal complex such as (4,6-F2ppy)2Irpic or an organometallic complex. Alternatively, the blue light emitting layer may include a phosphorescent material containing an organometallic complex such as (4,6-F2ppy)2Irpic.

According to some embodiments, a green light emitting layer emitting green light may include a fluorescent material containing Alq3(tris(8-Hydroxyquinolino)aluminum). A dopant material included in the green light emitting layer may be selected from, for example, a metal complex such as Ir(ppy)3(fac-tris(2-phenylpyridine)iridium or an organometallic complex.

According to some embodiments, a red light emitting layer emitting red light may include a fluorescent material containing PBD:Eu(DBM)3(Phen)(tris(dibenzoylmethanato)phenanthoroline europium) or perylene. At this time, the dopant material included in the red light emitting layer may be selected from, for example, a metal complex such as PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium) and PtOEP(octaethylporphyrin platinum) or an organometallic complex.

According to some embodiments, the first light emitting layer EML1-1, the second light emitting layer EML1-2, and the third light emitting layer EML1-3 may be sequentially stacked on the pixel electrode PE, but the arrangement order thereof may be variously changed according to embodiments. According to some embodiments, the first light emitting layer EML1-1, the second light emitting layer EML1-2, and the third light emitting layer EML1-3 may be continuously stacked without a separate charge generation layer CGL interposed therebetween and may constitute one stack (e.g., a first stack ST1 or a first light emitting unit). For example, the light emitting element ED may be an organic light emitting diode having a one-tandem structure.

The light emitting stack LES may further include at least one intermediate layer (e.g., at least one first intermediate layer) overlapping at least one light emitting layer. For example, the light emitting stack LES may include a first hole layer HL1 located between the pixel electrode PE and the first light emitting layer EML1-1, and a first electron layer EL1 located between the third light emitting layer EML1-3 and the common electrode CE.

The first hole layer HL1 may include at least one of a hole injection layer HIL or a hole transport layer HTL. For example, the first hole layer HL1 may include a hole transport layer or may include a hole transport layer and a hole injection layer. The hole transport layer may serve to smoothly transport holes and may include a hole transport material. The hole transport material may include a carbazole-based derivative such as N-phenylcarbazole and polyvinylcarbazole, a fluorene-based derivative, a triphenylamine-based derivative such as N,N′-bis(3-methylphenyl)-N,N′-diphenyl)-[1,1-biphenyl]-4,4′-diamine (TPD) and 4,4′,4″-tris(N-carbazolyl)triphenylamine (TCTA), N,N′-di(1-naphthyl)-N,N′-diphenylbenzidine (NPB), 4,4′-Cyclohexylidene bis[N,N-bis(4-methylphenyl)benzenamine] (TAPC), or the like, but is not limited thereto.

The first electron layer EL1 may include at least one of an electron transport layer ETL or an electron injection layer EIL. The first electron layer EL1 may be an element located on at least one light emitting layer and may be an optional element. For example, the light emitting stack LES may include or may not include the first electron layer EL1. The electron transport layer may serve to smoothly transport electrons and may include an electron transport material. The electron transport material may include an electron transport material such as tris(8-hydroxyquinolinato)aluminum (Alq3), 1,3,5-tri(1-phenyl-1H-benzo[d]imidazol-2-yl)phenyl (TPBi), 2,9-dimethyl-4,7-diphenyl-1,10-phenanthroline (BCP), (4,7-diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), bis(2-methyl-8-quinolinolato-N1,O8)-(1,1′-Biphenyl-4-olato)aluminum (BAlq), berylliumbis(benzoquinolin-10-olate (Bebq2), 9,10-di(naphthalene-2-yl)anthracene (ADN), and a mixture thereof, but embodiments according to the present disclosure are not limited thereto.

According to some embodiments, the light emitting element ED may further include an electron blocking layer located between the first hole layer HL1 and the first light emitting layer EML1-1. For example, the light emitting element ED may include an electron blocking layer located between the hole transport layer and the first light emitting layer EML1-1. The electron blocking layer may include a hole transport material and a metal or metal compound to prevent electrons generated in the first light emitting layer EML1-1 from moving into the first hole layer HL1. According to some embodiments, the hole transport layer and the electron blocking layer may be formed of a single layer in which each material is mixed.

According to some embodiments, the light emitting element ED may further include at least one buffer layer for stabilizing element characteristics. For example, the light emitting element ED may further include a buffer layer located between the third light emitting layer EML1-3 and the first electron layer EL1.

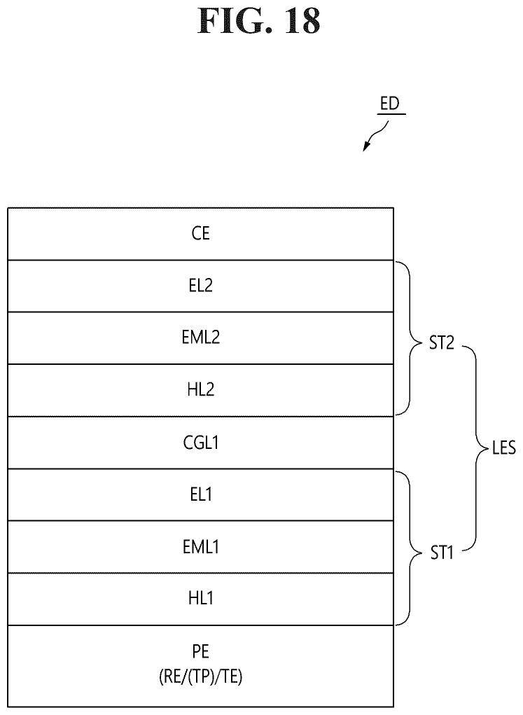

Referring to FIG. 18 in addition to FIGS. 1 to 17, the light emitting stack LES may include the first stack ST1 and a second stack ST2 overlapping each other. For example, the first stack ST1 and the second stack ST2 may be sequentially arranged on the pixel electrode PE. The light emitting stack LES may further include a first charge generation layer CGL1 located between the first stack ST1 and the second stack ST2. For example, the light emitting element ED may be an organic light emitting diode having a two-tandem structure.

Each of the first stack ST1 and the second stack ST2 may include at least one light emitting layer and at least one intermediate layer (e.g., at least one first intermediate layer and at least one second intermediate layer, respectively). For example, the first stack ST1 may include the first hole layer HL1, a first light emitting layer EML1, and the first electron layer EL1, and the second stack ST2 may include a second hole layer HL2, a second light emitting layer EML2, and a second electron layer EL2. The first hole layer HL1 and the first electron layer EL1 may overlap each other with the first light emitting layer EML1 interposed therebetween, and the second hole layer HL2 and the second electron layer EL2 may overlap each other with the second light emitting layer EML2 interposed therebetween.

According to some embodiments, each of the first stack ST1 and the second stack ST2 may selectively further include at least one of the electron blocking layer or the buffer layer. The electron blocking layer may be located between the hole layer and the light emitting layer of each stack. The buffer layer may be located between the light emitting layer and the electron layer of each stack.

Each of the first hole layer HL1 and the second hole layer HL2 may include at least one of the hole transport layer or the hole injection layer. Each of the first electron layer EL1 and the second electron layer EL2 may include at least one of the electron transport layer or the electron injection layer.

The first light emitting layer EML1 and the second light emitting layer EML2 may include a host and a dopant, and may generate light of the same or different colors. When the first light emitting layer EML1 and the second light emitting layer EML2 generate light of different colors, the first light emitting layer EML1 and the second light emitting layer EML2 may include different dopants. According to some embodiments, the first light emitting layer EML1 may be a blue light emitting layer generating light of a blue color, and the second light emitting layer EML2 may be a yellow light emitting layer generating light of a yellow color. The types of the first light emitting layer EML1 and the second light emitting layer EML2 and the color and/or wavelength of light generated by the first light emitting layer EML1 and the second light emitting layer EML2 may be variously changed according to embodiments. According to some embodiments, at least one of the first light emitting layer EML1 or the second light emitting layer EML2 may include at least two light emitting layers that emit light of different colors and are continuously stacked.

The first charge generation layer CGL1 may be a functional layer that plays a role of injecting charges into the first light emitting layer EML1 and the second light emitting layer EML2 and adjusting the charge balance between the first stack ST1 and the second stack ST2. The first charge generation layer CGL1 may include a negative charge generation layer and a positive charge generation layer. According to some embodiments, the negative charge generation layer and the positive charge generation layer may be bonded to each other and may be sequentially located between the first stack ST1 and the second stack ST2. For example, the negative charge generation layer may be located on the first stack ST1, and the positive charge generation layer may be located on the negative charge generation layer.

The negative charge generation layer may be arranged to be in contact with the first stack ST1 to supply electrons to the first light emitting layer EML1. The negative charge generation layer may include a host and a dopant. The host may include an organic material. The dopant may include a metal material. According to some embodiments, the negative charge generation layer may include an arylamine-based organic compound such as α-NPD, 2-TNATA, TDATA, MTDATA, sprio-TAD, or sprio-NPB.

The positive charge generation layer may be arranged to be in contact with the second stack ST2 to supply holes to the second light emitting layer EML2. The positive charge generation layer may include a host and a dopant. The host may include an organic material. The dopant may include a metal material. According to some embodiments, the positive charge generation layer may include a charge generating compound made of metal, metal oxide, carbide, and fluoride, or a mixture thereof. For example, the metal may be cesium (Cs), molybdenum (Mo), vanadium (V), titanium (Ti), tungsten (W), barium (Ba), or lithium (Li). In addition, for example, the metal oxide, carbide, and fluoride may be Re₂O₇, MoO₃, V₂O₅, WO₃, TiO₂, Cs₂CO₃, BaF, LiF, or CsF.

The first charge generation layer CGL1 may be located between the first stack ST1 and the second stack ST2 to provide charges to each light emitting layer, so that the luminous efficiency of the light emitting element ED may be increased and the driving voltage may be lowered.

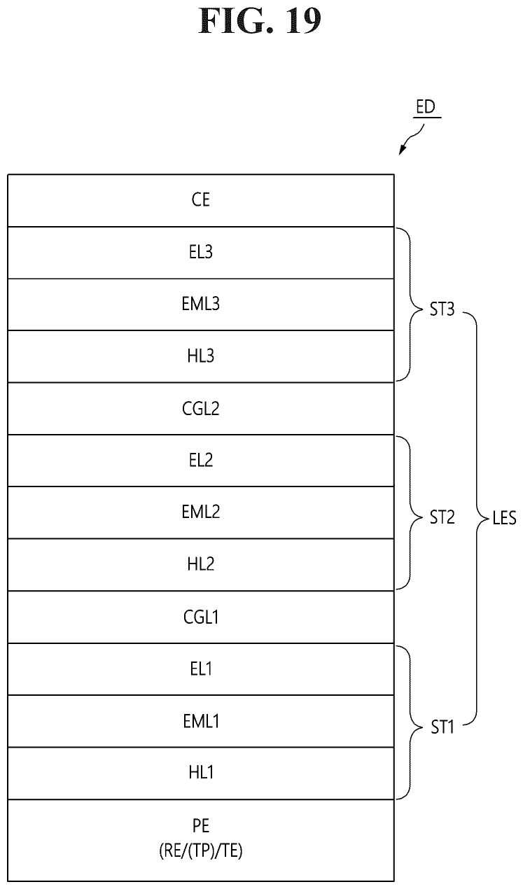

Referring to FIG. 19 in addition to FIGS. 1 to 18, the light emitting stack LES may further include a third stack ST3 overlapping the first stack ST1 and the second stack ST2. For example, the light emitting stack LES may further include a second charge generation layer CGL2 and the third stack ST3 sequentially arranged between the second stack ST2 and the common electrode CE. For example, the light emitting element ED may be an organic light emitting diode having a three-tandem structure.

The third stack ST3 may include a third light emitting layer EML3 and at least one intermediate layer (e.g., at least one third intermediate layer). For example, the third stack ST3 may include the third light emitting layer EML3, and a third hole layer HL3 and a third electron layer EL3 overlapping each other with the third light emitting layer EML3 interposed therebetween. For example, the third hole layer HL3, the third light emitting layer EML3, and the third electron layer EL3 of the third stack ST3 may be sequentially arranged on the second charge generation layer CGL2.

The third hole layer HL3 may include at least one of the hole transport layer or the hole injection layer. The third electron layer EL3 may include at least one of the electron transport layer or the electron injection layer.

The third light emitting layer EML3 may include a host and a dopant, and may generate light of the same color as the first light emitting layer EML1 and/or the second light emitting layer EML2, or generate light of a different color from the first light emitting layer EML1 and the second light emitting layer EML2. According to some embodiments, the first light emitting layer EML1, the second light emitting layer EML2, and the third light emitting layer EML3 may generate light of different colors.

According to some embodiments, the first light emitting layer EML1, the second light emitting layer EML2, and the third light emitting layer EML3 may be the green light emitting layer emitting light of a green color, the blue light emitting layer emitting light of a blue color, and the red light emitting layer emitting light of a red color, respectively. According to some embodiments, the first light emitting layer EML1, the second light emitting layer EML2, and the third light emitting layer EML3 may be the red light emitting layer, the green light emitting layer, and the blue light emitting layer, respectively.

According to some embodiments, the first light emitting layer EML1, the second light emitting layer EML2, and the third light emitting layer EML3 may be the blue light emitting layer, the green light emitting layer, and the red light emitting layer, respectively. For example, the arrangement order and/or position (e.g., arrangement height) of the blue light emitting layer, the green light emitting layer, and the red light emitting layer may be variously changed according to embodiments. According to some embodiments, the arrangement order and/or position of the blue light emitting layer, the green light emitting layer, and the red light emitting layer may be set to improve the light efficiency and lifespan of the light emitting elements ED and to increase or optimize the micro-cavity effect in the emission areas EA.

According to some embodiments, the third stack ST3 may selectively further include at least one of the electron blocking layer or the buffer layer. The electron blocking layer may be located between the third hole layer HL3 and the third light emitting layer EML3. The buffer layer may be located between the third light emitting layer EML3 and the third electron layer EL3.

The second charge generation layer CGL2 may be a functional layer that plays a role of injecting charges into the second light emitting layer EML2 and the third light emitting layer EML3 and adjusting the charge balance between the second stack ST2 and the third stack ST3. The second charge generation layer CGL2 may include a negative charge generation layer and a positive charge generation layer. According to some embodiments, the negative charge generation layer and the positive charge generation layer may be bonded to each other and may be sequentially arranged between the second stack ST2 and the third stack ST3. For example, the negative charge generation layer may be located on the second stack ST2, and the positive charge generation layer may be located on the negative charge generation layer.

The negative charge generation layer of the second charge generation layer CGL2 may be arranged to be in contact with the second stack ST2 to supply electrons to the second light emitting layer EML2. The positive charge generation layer of the second charge generation layer CGL2 may be arranged to be in contact with the third stack ST3 to supply holes to the third light emitting layer EML3. By arranging the second charge generation layer CGL2 between the second stack ST2 and the third stack ST3, the luminous efficiency of the light emitting element ED may be increased and the driving voltage may be lowered.

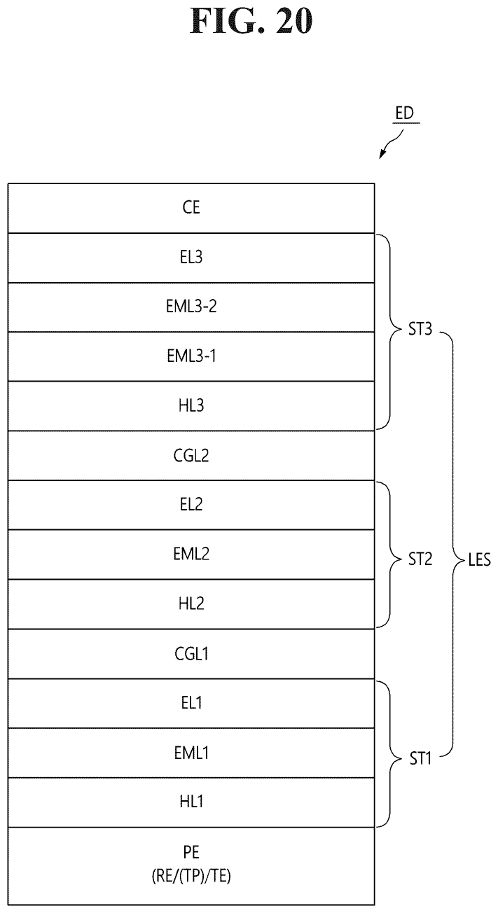

Referring to FIGS. 20 to 22 in addition to FIGS. 1 to 19, at least one stack included in the light emitting stack LES may include at least two light emitting layers that emit light of different colors and are continuously stacked. For example, one of the first stack ST1, the second stack ST2, and the third stack ST3 may include two light emitting layers sequentially arranged on the hole layer and emitting light of different colors, and the remaining stacks may include only a single light emitting layer. According to some embodiments, the one stack may include the red light emitting layer and the green light emitting layer that are successively stacked, and each of the remaining stacks may include one blue light emitting layer.

Referring to FIG. 20, the first stack ST1 and the second stack ST2 may include the first light emitting layer EML1 and the second light emitting layer EML2, respectively, and the third stack ST3 may include a third-first light emitting layer EML3-1 and a third-second light emitting layer EML3-2 sequentially arranged on the third hole layer HL3. According to some embodiments, each of the first light emitting layer EML1 and the second light emitting layer EML2 may be a light emitting layer that emits light of the first color, for example, the blue light emitting layer. One (e.g., the third-first light emitting layer EML3-1) of the third-first light emitting layer EML3-1 and the third-second light emitting layer EML3-2 may be a light emitting layer emitting light of the third color, for example, the red light emitting layer, and the other one thereof (e.g., the third-second light emitting layer EML3-2) of the third-first light emitting layer EML3-1 and the third-second light emitting layer EML3-2 may be a light emitting layer emitting light of the second color, for example, the green light emitting layer.

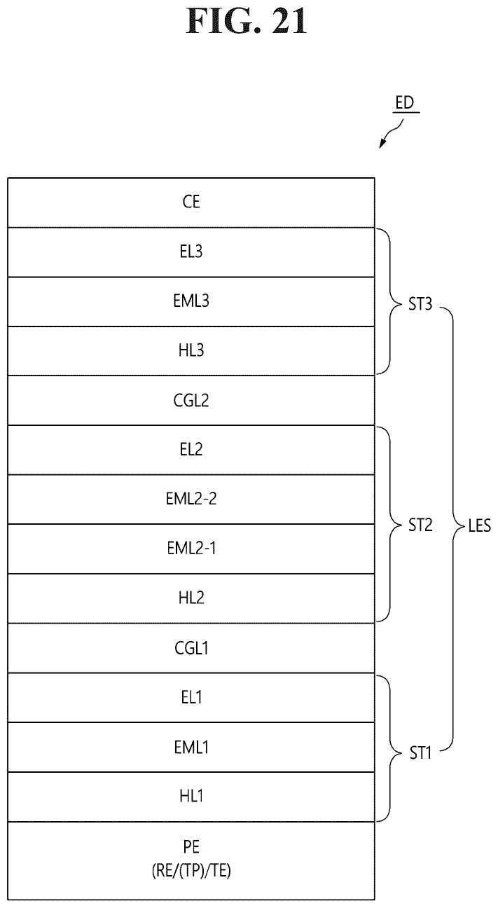

Referring to FIG. 21, the first stack ST1 and the third stack ST3 may include the first light emitting layer EML1 and the third light emitting layer EML3, respectively, and the second stack ST2 may include a second-first light emitting layer EML2-1 and a second-second light emitting layer EML2-2 sequentially arranged on the second hole layer HL2. According to some embodiments, each of the first light emitting layer EML1 and the third light emitting layer EML3 may be a light emitting layer that emits light of the first color, for example, the blue light emitting layer. One (e.g., the second-first light emitting layer EML2-1) of the second-first light emitting layer EML2-1 and the second-second light emitting layer EML2-2 may be a light emitting layer emitting light of the third color, for example, the red light emitting layer, and the other one thereof (e.g., the second-second light emitting layer EML2-2) of the second-first light emitting layer EML2-1 and the second-second light emitting layer EML2-2 may be a light emitting layer emitting light of the second color, for example, the green light emitting layer.

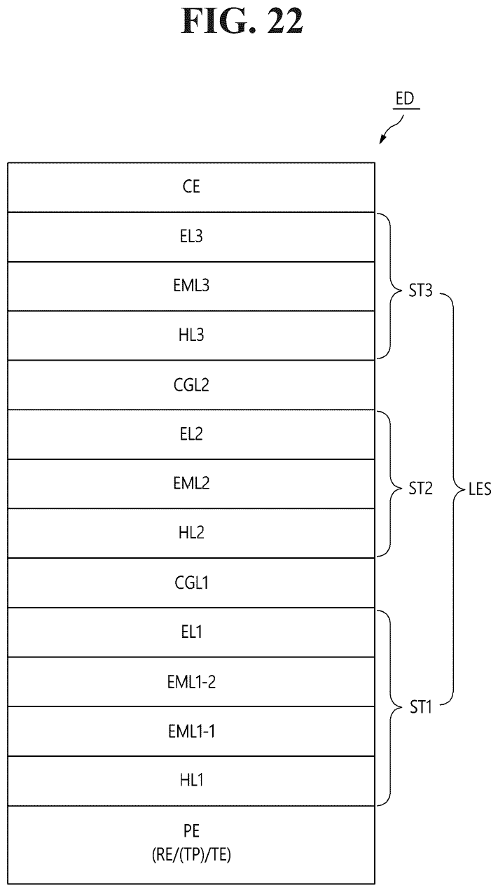

Referring to FIG. 22, the first stack ST1 may include a first-first light emitting layer EML1-1 and a first-second light emitting layer EML1-2 sequentially arranged on the first hole layer HL1, and the second stack ST2 and the third stack ST3 may include a second light emitting layer EML2 and a third light emitting layer EML3, respectively. According to some embodiments, one (e.g., the first-first light emitting layer EML1-1) of the first-first light emitting layer EML1-1 and the first-second light emitting layer EML1-2 may be the red light emitting layer, and the other one thereof (e.g., the first-second light emitting layer EML1-2) of the first-first light emitting layer EML1-1 and the first-second light emitting layer EML1-2 may be the green light emitting layer. Each of the second light emitting layer EML2 and the third light emitting layer EML3 may be the blue light emitting layer. For example, the arrangement order, number and/or type of the light emitting layers is not limited, and may be variously changed according to embodiments.

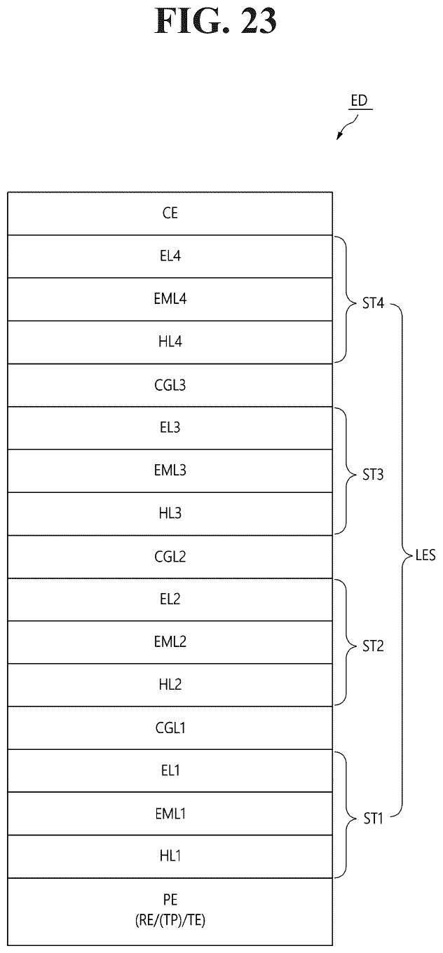

Referring to FIG. 23 in addition to FIGS. 1 to 19, the light emitting stack LES may further include a third charge generation layer CGL3 and a fourth stack ST4 sequentially arranged between the third stack ST3 and the common electrode CE. For example, the light emitting element ED may be an organic light emitting diode having a four-tandem structure.

The fourth stack ST4 may include a fourth light emitting layer EML4 and at least one intermediate layer (e.g., at least one fourth intermediate layer). For example, the fourth stack ST4 may include a fourth hole layer HL4, a fourth light emitting layer EML4, and a fourth electron layer EL4 sequentially arranged on the third charge generation layer CGL3.

The fourth hole layer HL4 may include at least one of the hole transport layer or the hole injection layer. The fourth electron layer EL4 may include at least one of the electron transport layer or the electron injection layer.

The fourth light emitting layer EML4 may include a host and a dopant, and may generate light of the same color as the first light emitting layer EML1, the second light emitting layer EML2, and/or the third light emitting layer EML3, or generate light of a different color from the first light emitting layer EML1, the second light emitting layer EML2, and the third light emitting layer EML3.

According to some embodiments, two light emitting layers among the first light emitting layer EML1, the second light emitting layer EML2, the third light emitting layer EML3, and the fourth light emitting layer EML4 may be the blue light emitting layers, and the remaining light emitting layers may be the green light emitting layer and the red light emitting layer, respectively. For example, the first light emitting layer EML1 located in the lowermost portion among the light emitting layers may be the blue light emitting layer. One of the second light emitting layer EML2, the third light emitting layer EML3, and the fourth light emitting layer EML4 may be the red light emitting layer, another one thereof may be the green light emitting layer, and the other one thereof may be the blue light emitting layer. For example, the second light emitting layer EML2, the third light emitting layer EML3, and the fourth light emitting layer EML4 may be the red light emitting layer, the green light emitting layer, and the blue light emitting layer, respectively.

According to some embodiments, the fourth stack ST4 may selectively further include at least one of the electron blocking layer or the buffer layer. The electron blocking layer may be located between the fourth hole layer HL4 and the fourth light emitting layer EML4. The buffer layer may be located between the fourth light emitting layer EML4 and the fourth electron layer EL4.

The third charge generation layer CGL3 may be a functional layer that plays a role of injecting charges into the third light emitting layer EML3 and the fourth light emitting layer EML4 and adjusting the charge balance between the third stack ST3 and the fourth stack ST4. The third charge generation layer CGL3 may include a negative charge generation layer and a positive charge generation layer. According to some embodiments, the negative charge generation layer and the positive charge generation layer may be bonded to each other and may be sequentially arranged between the third stack ST3 and the fourth stack ST4. For example, the negative charge generation layer may be located on the third stack ST3, and the positive charge generation layer may be located on the negative charge generation layer.

The negative charge generation layer of the third charge generation layer CGL3 may be arranged to be in contact with the third stack ST3 to supply electrons to the third light emitting layer EML3. The positive charge generation layer of the third charge generation layer CGL3 may be arranged to be in contact with the fourth stack ST4 to supply holes to the fourth light emitting layer EML4. By arranging the third charge generation layer CGL3 between the third stack ST3 and the fourth stack ST4, the luminous efficiency of the light emitting element ED may be increased and the driving voltage may be lowered.

As in the above-described embodiments, the light emitting element LD may include the light emitting stack LES having various configurations and/or stacked structures. When the light emitting element LD includes at least two light emitting layers, the arrangement order of the at least two light emitting layers may be determined in consideration of the reflection distance and the resonance distance for each order corresponding to light of the primary color (e.g., blue, green, or red) to be displayed in the pixels PX, and the light efficiency and/or lifespan of the pixels PX.

According to some embodiments, the distance between the light emitting layer located in the lowermost portion, for example, the first light emitting layer EML1 or EML1-1 and the pixel electrodes PE (or the reflective electrodes RE) may be approximately 500 Å to 2500 Å. For example, the thickness of the first hole layer HL1 may be approximately 500 Å to 2500 Å. As the first light emitting layer EML1 or EML1-1 and the pixel electrodes PE are spaced apart by a distance of approximately 500 Å or more, the injection and/or transport of the first carriers (e.g., holes) may be smoothly performed. As the first light emitting layer EML1 or EML1-1 and the pixel electrodes PE are spaced apart by a distance of approximately 2500 Å or less, the resonance distance of light corresponding to the primary colors of the pixels PX may be smoothly and/or appropriately secured. For example, it is possible to appropriately secure a resonance distance corresponding to an order that is set for blue light having a relatively short wavelength.

According to some embodiments, the distance between the light emitting layer located in the uppermost portion and the common electrode CE may be approximately 500 Å or less. For example, the thickness of the electron layer most adjacent to the common electrode CE may be approximately 500 Å or less. Accordingly, the injection of the second carriers (e.g., electrons) may be smoothly performed.

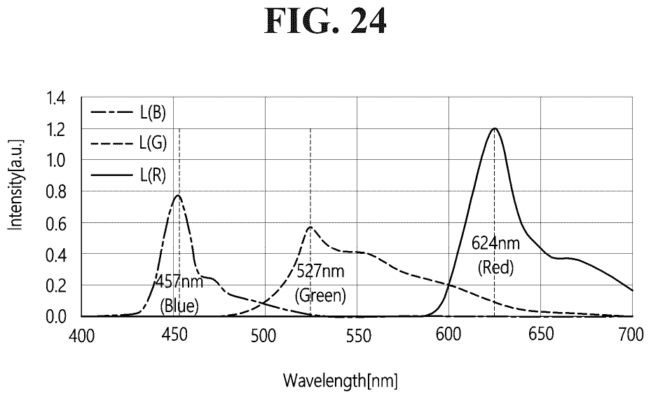

FIG. 24 is a graph illustrating spectrums of light emitted from the first light emitting layer EML1, the second light emitting layer EML2, and the third light emitting layer EML3 of the light emitting element ED according to some embodiments. For example, FIG. 24 illustrates the intensity and peak wavelength of the blue light L(B), the green light L(G), and the red light L(R) emitted from the first light emitting layer EML1, the second light emitting layer EML2, and the third light emitting layer EML3, respectively.

Referring to FIG. 24 in addition to FIGS. 9 to 23, the first light emitting layer EML1 may emit the blue light L(B) having a wavelength range of approximately 430 nm to 500 nm and having a peak wavelength at approximately 457 nm. The second light emitting layer EML2 may emit the green light L(G) having a wavelength range of approximately 500 nm to 570 nm and having a peak wavelength at approximately 527 nm. The third light emitting layer EML3 may emit the red light L(R) having a wavelength range of approximately 610 nm to 680 nm and having a peak wavelength at approximately 624 nm. The aforementioned wavelength range is illustrative, and the wavelength range and peak wavelength of light emitted from each light emitting layer may vary according to various embodiments.

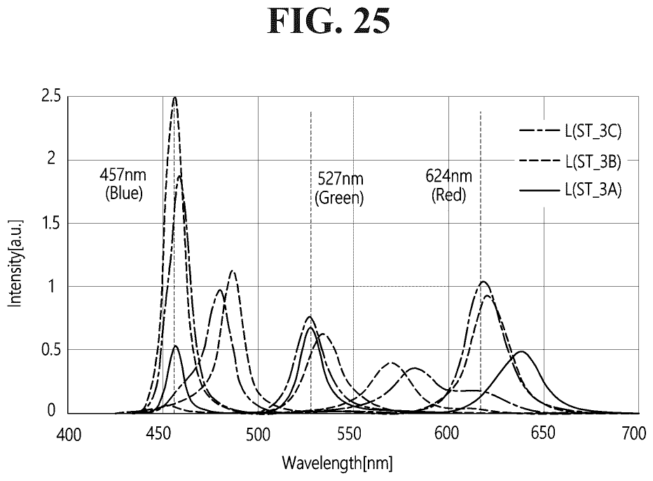

FIG. 25 is a graph illustrating spectrums of light emitted from the light emitting elements ED according to each of the embodiments. For example, FIG. 25 illustrates intensities and peak wavelengths according to the wavelength of light L(ST_3A), L(ST_3B), and L(ST_3C) emitted from the light emitting element ED of the three-tandem structure according to the embodiments of FIG. 19, the embodiments of FIG. 20, and the embodiments of FIG. 21, respectively.

Referring to FIG. 25 in addition to FIGS. 9 to 24, the spectrum of light emitted from each of the light emitting elements ED may vary according to the stack structure (e.g., the structure of the light emitting stack LES) of each of the light emitting elements ED, the type, number, and/or stacking order of light emitting layers, or the like. For example, the intensity and/or peak wavelength of light emitted from each of the light emitting elements ED may vary according to the stack structure of each of the light emitting elements ED, the type, number, and/or stacking order of light emitting layers, or the like.

According to some embodiments, when the light emitting element ED includes a plurality of light emitting layers emitting light of the same color, light emitted from the plurality of light emitting layers may have greater intensity. For example, as in the embodiments of FIGS. 20 and 21, when each of the light emitting elements ED includes four light emitting layers, two light emitting layers thereof are the blue light emitting layers, and the remaining light emitting layers thereof are the red light emitting layer and the green light emitting layer, respectively, the light emitting element ED may emit blue light with a higher intensity. Accordingly, the efficiency and lifespan of the blue light emitting layers and the light emitting element ED including the blue light emitting layers may be improved. The type, number, stacking order, or the like of the light emitting layers provided in each of the light emitting elements ED may be selected or determined in consideration of the efficiency and lifespan of each light emitting layer and the efficiency and lifespan of the light emitting element ED including the light emitting layers.

According to some embodiments, when the light emitting element ED includes at least two light emitting layers emitting light of the same color, one light emitting layer of the at least two light emitting layers may be arranged to be most adjacent to the pixel electrode PE compared to the other light emitting layers. For example, when the light emitting element ED includes two blue light emitting layers, one red light emitting layer, and one green light emitting layer, one of the two blue light emitting layers may be located in the first stack ST1. Accordingly, the light efficiency and lifespan of the light emitting element ED may be improved.

According to some embodiments, the front surface emission type display device DD having a resonance structure (e.g., an N-order resonance structure for each emission area EA) optimized for light to be emitted from the emission area EA of each of the pixels PX by using the light transmitting patterns TP, may be provided. For example, the distance between each of the reflective electrodes RE and the common electrode CE may be individually adjusted by using the light transmitting patterns TP such that in the emission area EA of each of the pixels PX, light of a specific color corresponding to the primary color of the corresponding pixel PX multi-resonates in a second or higher order and the micro-cavity effect is increased or optimized. Accordingly, the light efficiency of the pixels PX and the display device DD including the pixels PX may be improved while the driving voltage of the pixels PX is reduced.

In embodiments, the light emitting elements ED of the pixels PX may include the light emitting stack LES formed entirely in the display area DA in the form of a common layer. Accordingly, each layer of the light emitting stack LES may be formed using an open mask that is collectively opened to correspond to the display area DA. Accordingly, it is possible to easily manufacture or provide the high-resolution display device DD.

In some embodiments, each of the pixels PX may include the light emitting element ED having a tandem structure. Accordingly, the color reproducibility and lifespan of the pixels PX and the display device DD including the pixels PX may be improved.

In some embodiments, the light emitting elements ED may include at least two light emitting layers that generate light of a specific color with relatively poor luminous efficiency and lifespan. For example, the light emitting stack LES of the light emitting elements ED according to some embodiments may include two blue light emitting layers. Accordingly, light efficiency and lifespan of the pixels PX and the display device DD including the pixels PX may be improved.

In embodiments in which the light emitting elements ED include at least two light emitting layers (e.g., at least two blue light emitting layers) emitting light of a specific color (e.g., blue light), one of the at least two light emitting layers may be located at a lower portion more adjacent to each of the pixel electrodes PE than the remaining light emitting layers. Accordingly, the light efficiency and lifespan of the pixels PX and the display device DD including the pixels PX may be further improved and/or optimized.

In concluding the detailed description, those skilled in the art will appreciate that many variations and modifications can be made to the embodiments according to the present disclosure without substantially departing from the spirit and scope of embodiments according to the present disclosure. Therefore, the disclosed embodiments of the invention are used in a generic and descriptive sense only and not for purposes of limitation.

What is claimed is:

1. A display device comprising:
a first pixel electrode comprising a first reflective electrode in a first emission area, a first light transmitting pattern on a part of the first reflective electrode and containing an insulating material, and a first light transmitting electrode on the first reflective electrode and the first light transmitting pattern and connected to the first reflective electrode;
a second pixel electrode comprising a second reflective electrode in a second emission area and a second light transmitting electrode on the second reflective electrode;
a light emitting stack on the first pixel electrode and the second pixel electrode and comprising at least one light emitting layer; and
a common electrode on the light emitting stack,
wherein the first light transmitting pattern is formed as a separation type pattern locally on the first reflective electrode,
the light emitting stack is a common layer entirely over a display area comprising the first emission area and the second emission area, and
a first distance between the first reflective electrode and the common electrode is greater than a second distance between the second reflective electrode and the common electrode.

2. The display device of claim 1, further comprising a bank pattern between the first pixel electrode and the second pixel electrode, containing a same insulating material as the first light transmitting pattern, and spaced apart from the first light transmitting pattern.

3. The display device of claim 2, wherein the bank pattern surrounds the first emission area and the second emission area, and at least a part of the bank pattern is between the first emission area and the second emission area.

4. The display device of claim 1, further comprising:
a first color filter on the common electrode to correspond to the first emission area, and configured to selectively transmit light of a first color; and
a second color filter on the common electrode to correspond to the second emission area, and configured to selectively transmit light of a second color.

5. The display device of claim 4, wherein the first distance corresponds to a resonance distance of the light of the first color, and
the second distance corresponds to a resonance distance of the light of the second color.

6. The display device of claim 1, wherein the common electrode is a semi-transmissive type thin film electrode containing metal.

7. The display device of claim 1, further comprising a third pixel electrode comprising a third reflective electrode in a third emission area, a second light transmitting pattern on a part of the third reflective electrode, and a third light transmitting electrode on the third reflective electrode and the second light transmitting pattern and connected to the third reflective electrode,
wherein a part of each of the light emitting stack and the common electrode is on the third pixel electrode.

8. The display device of claim 7, wherein the first light transmitting pattern and the second light transmitting pattern contain a same insulating material and have different thicknesses.

9. The display device of claim 7, wherein the second pixel electrode further comprises a third light transmitting pattern on a part of the second reflective electrode and containing an insulating material, and
the second light transmitting electrode is on the second reflective electrode and the third light transmitting pattern and is connected to the second reflective electrode.

10. The display device of claim 9, wherein the first light transmitting pattern, the second light transmitting pattern, and the third light transmitting pattern contain a same insulating material.

11. The display device of claim 1, wherein the light emitting stack comprises:
a first light emitting layer configured to emit light of a first color; and
a second light emitting layer configured to emit light of a second color.

12. The display device of claim 11, wherein the light emitting stack comprises:
a first stack comprising the first light emitting layer, and a first hole layer and a first electron layer overlapping each other with the first light emitting layer interposed therebetween; and
a second stack on the first stack, and comprising the second light emitting layer, and a second hole layer and a second electron layer overlapping each other with the second light emitting layer interposed therebetween.

13. The display device of claim 12, wherein the light emitting stack further comprises a third stack overlapping the first stack and the second stack and comprising a third light emitting layer emitting the light of the first color, and a third hole layer and a third electron layer overlapping each other with the third light emitting layer interposed therebetween.

14. The display device of claim 13, wherein the first stack is closer to the first pixel electrode and the second pixel electrode than the second stack and the third stack, and
the first light emitting layer is configured to emit blue light.

15. A display device comprising:
a first pixel electrode comprising a first reflective electrode in a first emission area, a first light transmitting pattern on a part of the first reflective electrode, and a first light transmitting electrode on the first reflective electrode and the first light transmitting pattern and connected to the first reflective electrode;
a second pixel electrode comprising a second reflective electrode in a second emission area and a second light transmitting electrode on the second reflective electrode;
a light emitting stack on the first pixel electrode and the second pixel electrode and comprising at least one light emitting layer;
a common electrode on the light emitting stack; and
a bank pattern surrounding the first emission area and the second emission area, and having at least a portion positioned between the first emission area and the second emission area,
wherein the first light transmitting pattern and the bank pattern contain a same material and are spaced apart from each other.

16. The display device of claim 15, wherein the first light transmitting pattern is formed in a separation type pattern locally on the first reflective electrode, and
the light emitting stack is a common layer entirely over a display area comprising the first emission area and the second emission area.

17. The display device of claim 15, wherein the light emitting stack comprises:
a first light emitting layer configured to emit light of a first color; and
a second light emitting layer configured to emit light of a second color.

18. The display device of claim 17, further comprising:
a first color filter on the common electrode to correspond to the first emission area, and configured to selectively transmit light of a first color; and
a second color filter on the common electrode to correspond to the second emission area, and configured to selectively transmit light of a second color.

19. The display device of claim 18, wherein a first distance between the first reflective electrode and the common electrode corresponds to a resonance distance of the light of the first color, and
a second distance between the second reflective electrode and the common electrode corresponds to a resonance distance of the light of the second color.

20. The display device of claim 17, wherein the light emitting stack comprises:
a first stack comprising the first light emitting layer and at least one first intermediate layer;
a second stack on the first stack, and comprising the second light emitting layer and at least one second intermediate layer; and
a third stack on the second stack, and comprising a third light emitting layer and at least one third intermediate layer,
wherein the first light emitting layer is configured to emit blue light.
